(19) United States
(12) Patent Application Publication
(10) Pub. No.: US 2025/0393456 A1
(43) Pub. Date: Dec. 25, 2025

(54) DISPLAY DEVICE

(71) Applicant: Samsung Display Co., LTD., Yongin-si (KR)

(72) Inventors: Dae Geun LEE, Yongin-si (KR); Jeong Min BAN, Yongin-si (KR); Eun Jeong JEON, Yongin-si (KR)

(21) Appl. No.: 19/057,405

(22) Filed: Feb. 19, 2025

(30) Foreign Application Priority Data
Jun. 24, 2024 (KR) 10-2024-0081867

(51) Int. Cl. H10K 59/88; H10K 59/131

(52) U.S. Cl. CPC H10K 59/88; H10K 59/131

(57) ABSTRACT

The present disclosure provides a display device including a display panel, a first alignment mark in a first non-circuit area of the display panel, and having a closed curve shape surrounding at least a part of the first non-circuit area, a display driver connected to the display panel, and a second alignment mark in a second non-circuit area of the display driver, and surrounded by the second non-circuit area.

### CROSS-REFERENCE TO RELATED APPLICATION

The present application claims priority to, and the benefit of, Korean Patent Application No. 10-2024-0081867, filed on Jun. 24, 2024, in the Korean Intellectual Property Office, the disclosure of which is incorporated herein by reference.

### BACKGROUND

### 1. Field

The present disclosure relates to a display device capable of improving a discrimination ability of an alignment mark.

### 2. Description of the Related Art

Because an organic light-emitting diode (OLED) display is self-emissive and does not require a separate light source unlike a liquid crystal display, its thickness and weight may be reduced. In addition, an OLED display has garnered attention as a next-generation display for TVs, monitors, and portable electronic devices due to its superior characteristics, such as low power consumption, high luminance, and high response speed.

### SUMMARY

Aspects of the present disclosure provide a display device capable of improving a discernment ability of an alignment mark.

According to one or more embodiments of the present disclosure, there is provided a display device including a display panel, a first alignment mark in a first non-circuit area of the display panel, and having a closed curve shape surrounding at least a part of the first non-circuit area, a display driver connected to the display panel, and a second alignment mark in a second non-circuit area of the display driver, and surrounded by the second non-circuit area.

The first alignment mark and the second alignment mark may include metal.

The first alignment mark may be at an edge of the first non-circuit area.

The second alignment mark may be at a central portion of the second non-circuit area.

The second non-circuit area may have an area that is larger than that of the first non-circuit area.

An inner region defined by the first alignment mark may have an area that is larger than that of the second alignment mark.

An inner region defined by the first alignment mark may have an area that is smaller than that of the second non-circuit area.

The first alignment mark may surround an insulating film of the first non-circuit area in plan view.

The second alignment mark may be surrounded by an insulating film of the second non-circuit area in plan view.

The first alignment mark may surround the second alignment mark in plan view.

An edge of the second non-circuit area may surround the first alignment mark in plan view.

The display device may further include a first dummy pattern in the display panel, and at a different layer from the first alignment mark.

The first dummy pattern may be closer to a substrate of the display panel than the first alignment mark.

The first dummy pattern may be surrounded by the first alignment mark in plan view.

The first dummy pattern may be adjacent a corner of the first alignment mark in plan view.

The first dummy pattern may be in a remaining portion excluding a corner adjacent the first alignment mark.

The first alignment mark may include an outer pattern at an edge of the first non-circuit area, and a protrusion pattern protruding from the outer pattern.

The display device may further include a second dummy pattern in the display driver, and at a different layer from the second alignment mark.

The second dummy pattern may be closer to a substrate of the display driver than the second alignment mark.

The display device may further include a third alignment mark in the display panel adjacent to the first alignment mark.

The third alignment mark may be adjacent an edge of the display driver.

The display device may further include an auxiliary alignment mark in the second non-circuit area adjacent to one side of the second alignment mark.

The first alignment mark may have a quadrilateral shape.

The second alignment mark may have a cross shape.

According to one or more embodiments of the present disclosure, there is provided an electronic device including a display device including a display panel, a first alignment mark in a first non-circuit area of the display panel, and having a closed curve shape surrounding at least a part of the first non-circuit area, a display driver connected to the display panel, and a second alignment mark in a second non-circuit area of the display driver, and surrounded by the second non-circuit area.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

In accordance with the display device of the present disclosure, the discernment ability of the alignment mark may be improved. Therefore, even if the display device is manufactured on a wafer including many conductive layers, a first alignment mark of a display panel and a second alignment mark of a display driver may be accurately recognized by an imaging device. Therefore, the alignment operation of the display panel and the display driver may be easily performed.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to one or more embodiments;

FIG. 2 is a plan view illustrating a display unit of a display device according to one or more embodiments;

FIG. 3 is a block diagram illustrating a display panel and a display driver according to one or more embodiments;

FIG. 4 is a layout diagram showing one or more embodiments of the display area of FIG. 3;

FIG. 5 is a cross-sectional view illustrating an example of a display panel taken along the line I-I′ of FIG. 4;

FIG. 6 is an enlarged view of area A1 of FIG. 2;

FIG. 7 is an enlarged view of area A2 of FIG. 6;

FIG. 8 is a view selectively showing only a display panel, a first alignment mark, and a pad in FIG. 7;

FIG. 9 is a view selectively showing only a display driver, a second alignment mark, and a terminal in FIG. 7;

FIG. 10 is a cross-sectional view taken along the line II-II′ of FIG. 7;

FIG. 11 is a plan view of the display panel according to one or more embodiments;

FIG. 12 is a plan view of the display driver according to one or more embodiments;

FIG. 13 is a cross-sectional view taken along the line III-III′ of FIGS. 11 and 12 when the display panel of FIG. 11 and the display driver of FIG. 12 are connected to each other;

FIG. 14 is a plan view of the display panel according to one or more embodiments;

FIG. 15 is a cross-sectional view taken along the line IV-IV′ of FIG. 14 when the display panel of FIG. 14 and the display driver of FIG. 9 are connected to each other;

FIG. 16 is a plan view of the display panel according to one or more embodiments;

FIG. 17 is a plan view of the display panel according to one or more embodiments;

FIG. 18 is a plan view of the display panel according to one or more embodiments;

FIG. 19 is a plan view of the display panel according to one or more embodiments;

FIG. 20 is a plan view of the display panel according to one or more embodiments;

FIG. 21 is a plan view of the display panel according to one or more embodiments;

FIG. 22 is a plan view of the display panel according to one or more embodiments;

FIG. 23 is a plan view of the display panel according to one or more embodiments;

FIG. 24 is a plan view of the display panel according to one or more embodiments;

FIG. 25 is a plan view of the display panel according to one or more embodiments;

FIG. 26 is a plan view of the display driver according to one or more embodiments;

FIG. 27 is a plan view of the display driver according to one or more embodiments;

FIG. 28 is a plan view of the display driver according to one or more embodiments;

FIG. 29 is a plan view of the display driver according to one or more embodiments;

FIG. 30 is a plan view of the display driver according to one or more embodiments;

FIG. 31 is an enlarged view of area A1 of FIG. 2 according to one or more other embodiments;

FIG. 32 is an enlarged view of area A3 of FIG. 31;

FIGS. 33 to 39 are views illustrating a method of manufacturing a display device according to one or more embodiments; and

FIG. 40 is a view illustrating a method of manufacturing a display device according to one or more embodiments.

FIG. 41 is a block diagram of an electronic device according to one embodiment.

FIGS. 42, 43 and 44 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

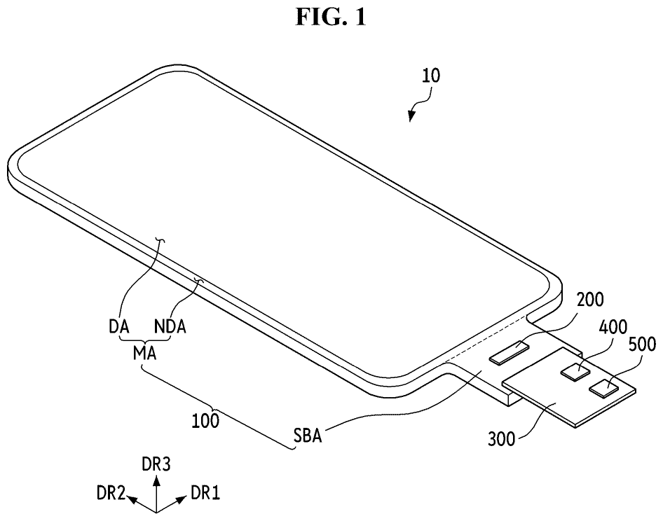

FIG. 1 is a perspective view showing a display device according to one or more embodiments.

Referring to FIG. 1, a display device 10 may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display unit of a television, a laptop, a monitor, a billboard, or an Internet-of-Things (IoT) device. For another example, the display device 10 may be applied to wearable devices, such as a smart watch, a watch phone, a glasses type display, or a head-mounted display (HMD).

The display device 10 may have a planar shape similar to a quadrilateral shape. For example, the display device 10 may have a planar shape similar to a quadrilateral shape having a short side in a first direction DR1 and a long side in a second direction DR2. A corner where the short side in the first direction DR1 and the long side in the second direction DR2 meet may be right-angled or rounded with a corresponding curvature. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA. The main region MA may include a display area DA including pixels displaying an image and a non-display area NDA located around the display area DA. The display area DA may emit light from a plurality of emission areas or a plurality of opening areas. For example, the display panel 100 may include a pixel circuit PC including switching elements, a pixel-defining film defining an emission area or an opening area, and a self-light-emitting element LEL.

For example, the self-light-emitting element LEL may include at least one of an organic light-emitting diode (LED) including an organic light-emitting layer, a quantum dot LED including a quantum dot light-emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. In one or more embodiments, the non-display area NDA may include a gate driver that supplies gate signals to the gate lines, and fan-out lines that connect the display driver 200 to the display area DA.

The sub-region SBA may extend from one side of the main region MA. The sub-region SBA may include a flexible material which can be bent, folded or rolled. For example, when the sub-region SBA is bent, the sub-region SBA may overlap the main region MA in a thickness direction (e.g., a third direction DR3). The sub-region SBA may include the display driver 200 and a pad connected to the circuit board 300. Optionally, the sub-region SBA may be omitted, and the display driver 200 and the pad may be located in the non-display area NDA.

The display driver 200 may output signals and voltages for driving the display panel 100. The display driver 200 may supply data voltages to data lines DL. The display driver 200 may supply a power voltage to the power line, and may supply a gate control signal to the gate driver. The display driver 200 may be formed as an integrated circuit (IC) and mounted on the display panel 100 by a chip-on-glass (COG) method, a chip-on-plastic (COP) method, or an ultrasonic bonding method. For example, the display driver 200 may be located in the sub-region SBA, and may overlap the main region MA in the thickness direction (third direction DR3) by bending of the sub-region SBA. For another example, the display driver 200 may be mounted on the circuit board 300.

The circuit board 300 may be attached to the pad of the display panel 100 by using an anisotropic conductive film (ACF). Lead lines of the circuit board 300 may be electrically connected to the pad of the display panel 100. The circuit board 300 may be a flexible printed circuit board, a printed circuit board, or a flexible film, such as a chip on film.

The touch driver 400 may be mounted on the circuit board 300.

The power supply unit 500 may be located on the circuit board 300 to supply a power voltage to the display driver 200 and the display panel 100 (as used herein, “located on” may mean “above” or “below”). The power supply unit 500 may generate a driving voltage to supply it to a driving voltage line VDL, and may generate a common voltage to supply it to a common electrode that is common to the light-emitting elements of a plurality of pixels. For example, the driving voltage may be a high potential voltage for driving the light-emitting element, and the common voltage may be a low potential voltage for driving the light-emitting element.

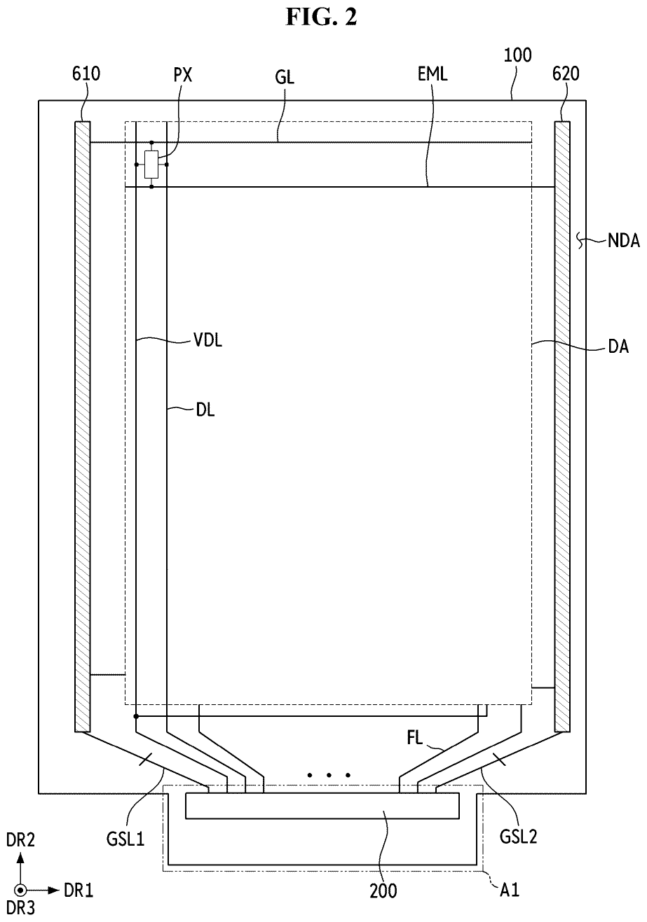

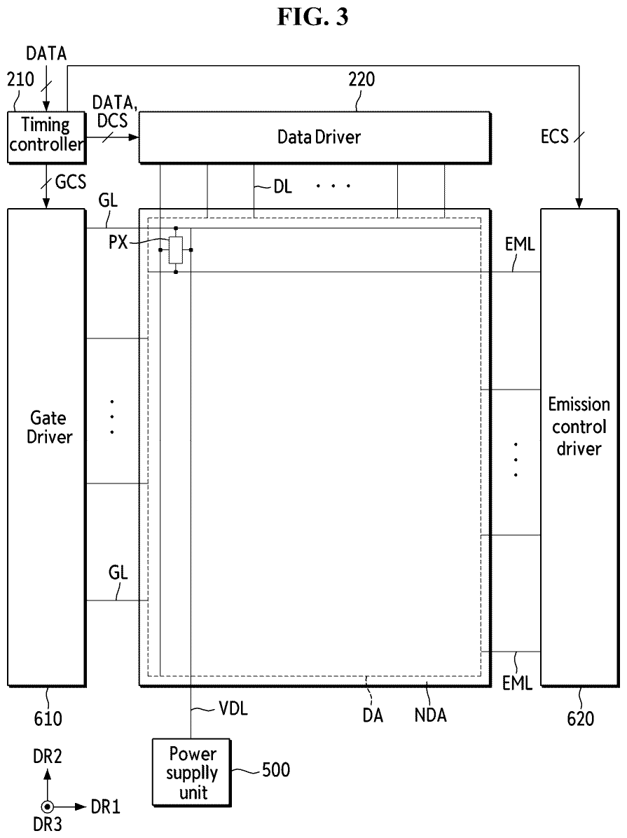

FIG. 2 is a plan view illustrating a display unit of a display device according to one or more embodiments. FIG. 3 is a block diagram illustrating a display panel and a display driver according to one or more embodiments.

Referring to FIGS. 2 and 3, the display panel 100 may include the display area DA and the non-display area NDA.

The display area DA may include a plurality of pixels PX, and a plurality of signal transmission lines connected to the plurality of pixels PX. Here, the plurality of signal transmission lines may include a plurality of gate lines of a plurality of common voltage lines, a plurality of emission lines EML and a plurality of data lines DL, and fan-out lines FL connected to the aforementioned lines.

Each of the plurality of pixels PX may be connected to the gate line, the data line DL, the emission line EML, the driving voltage line VDL, and the common voltage line. Each of the pixels PX may include at least one transistor, the light-emitting element and a capacitor.

Each of the gate lines may extend in the first direction DR1, and may be spaced apart from each other in the second direction DR2 crossing the first direction DR1. The gate lines may be arranged along the second direction DR2. The gate lines may sequentially supply gate signals to the plurality of pixels PX.

The emission lines EML may each extend in the first direction DR1, and may be spaced apart from each other in the second direction DR2. The emission line EML may be arranged along the second direction DR2. The emission lines EML may sequentially supply an emission signal to the plurality of pixels PX.

The data lines DL may extend in the second direction DR2, and may be spaced apart from each other in the first direction DR1. The data lines DL may be arranged along the first direction DR1. The data lines DL may supply data voltages to the plurality of pixels PX. The data voltage may determine the luminance of each of the pixels PX.

The driving voltage lines VDL may extend in the second direction DR2, and may be spaced apart from each other in the first direction DR1. The driving voltage lines VDL may be arranged along the first direction DR1. The driving voltage lines VDL may supply a driving voltage to the plurality of pixels PX. The driving voltage may be a high potential voltage for driving the light-emitting element of the pixels PX.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from one side of the non-display area NDA. The sub-region SBA may include the display driver 200 and the pad. The pad may be electrically connected to the display driver 200 and the circuit board 300 through an anisotropic conductive film (ACF).

The display driver 200 may include a timing controller 210 and a data driver 220. The timing controller 210 may receive a digital video data signal DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission control driver 620. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data signal DATA and the data control signal DCS to the data driver 220.

The data driver 220 may convert the digital video data signal DATA into analog data voltages, and may supply them to the data lines DL through the fan-out lines FL. The gate signals of the gate driver 610 may select the pixels PX to which the data voltage is supplied, and the selected pixels PX may receive the data voltage through the data lines DL.

The power supply unit 500 may be located on the circuit board 300 to supply a power voltage to the display driver 200 and the display panel 100. The power supply unit 500 may generate a driving voltage to supply it to the driving voltage line VDL, and may generate a common voltage to supply it to a common electrode that is common to the light-emitting elements of a plurality of pixels.

The gate driver 610 may be located at one external side of the display area DA or at one side of the non-display area NDA. The emission control driver 620 may be located at the other external side of the display area DA or at the other side of the non-display area NDA. However, the present disclosure is not limited thereto. As another example, the gate driver 610 and the emission control driver 620 may be located at any one of one side or the other side of the non-display area NDA.

The gate driver 610 may include a plurality of transistors for generating gate signals based on the gate control signal GCS. The emission control driver 620 may include a plurality of transistors that generate the emission signals based on the emission control signal ECS. For example, the transistors of the gate driver 610 and the transistors of the emission control driver 620 may be formed on the same layer as the transistors of each of the pixels PX. The gate driver 610 may supply the gate signals to the gate lines, and the emission control driver 620 may supply the emission signals to the emission lines EML.

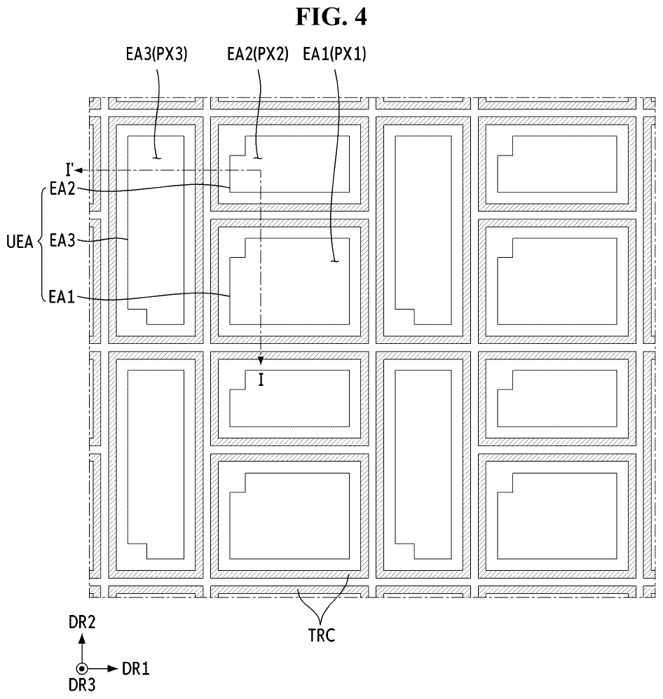

FIG. 4 is a layout diagram showing one or more embodiments of the display area of FIG. 3.

Referring to FIG. 4, each of unit pixels may include a first emission area EA1 as an emission area of a first pixel PX1, a second emission area EA2 as an emission area of a second pixel PX2, and a third emission area EA3 as an emission area of a third pixel PX3. In other words, the unit pixel may include a unit emission area UEA, and the unit emission area UEA may include the first emission area EA1, the second emission area EA2, and the third emission area EA3 described above.

Referring to FIG. 4, each of the plurality of pixels PX may include the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in plan view.

The maximum length of the third emission area EA3 in the first direction DR1 may be less than the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than the maximum length of the second emission area EA2 in the second direction DR2 and the maximum length of the first emission area EA1 in the second direction DR2. The maximum length of the first emission area EA1 in the second direction DR2 may be greater than the maximum length of the second emission area EA2 in the second direction DR2.

As shown in FIG. 4, in each of the plurality of pixels PX, the third emission area EA3 and the second emission area EA2 may be adjacent to each other in the first direction DR1. Further, the first emission area EA1 and the third emission area EA3 may be adjacent to each other in the first direction DR1. In addition, the second emission area EA2 and the first emission area EA1 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

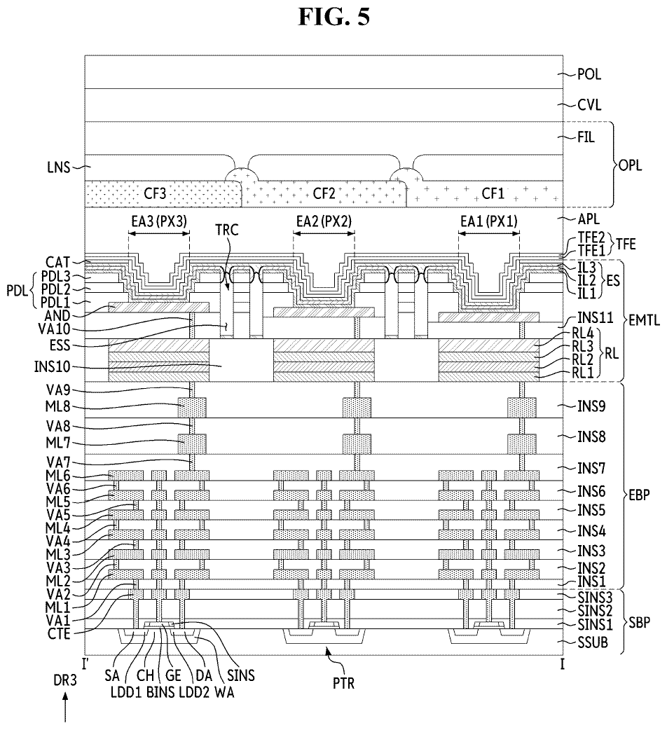

FIG. 5 is a cross-sectional view illustrating an example of a display panel taken along the line I-I′ of FIG. 4.

Referring to FIG. 5, the display panel 100 may include a semiconductor backplane SBP, a light-emitting element backplane EBP, a display element layer EMTL, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a wafer or substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but the present disclosure is not limited thereto.

A second semiconductor insulating film SINS2 may be located on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP may include a plurality of insulating films INS1 to INS11 located between the first to eighth conductive layers ML1 to ML8.

The first to eighth conductive layers ML1 to ML8 may serve to connect the plurality of contact terminals CTE exposed from the semiconductor backplane SBP to thereby implement a circuit of a pixel (e.g., the first pixel PX1). For example, the plurality of pixel transistors PTR may be formed on the semiconductor backplane SBP, and the connection between the plurality of pixel transistors PTR and the capacitor of the pixel may be accomplished through the first to eighth conductive layers ML1 to ML8. Further, the pixel transistor may include a driving transistor for driving a light-emitting element, and the connection between the drain region corresponding to the drain electrode of the driving transistor and the first electrode of the light-emitting element may also be accomplished through the first to eighth conductive layers ML1 to ML8. Here, the first to eighth conductive layers ML1 to ML8 may be made of a material containing metal, for example.

The first insulating film INS1 may be located on the semiconductor backplane SBP. Each of the first vias VA1 may penetrate the first insulating film INS1, and may be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2, and may be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3, and may be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4, and may be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5, and may be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6, and may be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7, and may be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8, and may be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be located on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9, and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The display element layer EMTL may be located on the light-emitting element backplane EBP. The display element layer EMTL may include the light-emitting elements each including a reflective electrode layer RL, tenth and eleventh insulating films INS10 and INS11, a tenth via VA10, a first electrode AND, a light-emitting stack ES, and a second electrode CAT. The display element layer EMTL may also include a pixel-defining film PDL, and a plurality of trenches TRC.

The reflective electrode layer RL may be located on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 5.

Each of the first reflective electrodes RL1 may be located on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be located on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be located on a corresponding second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TN).

Each of the fourth reflective electrodes RL4 may be located on a corresponding third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Because the second reflective electrode RL2 is an electrode that substantially reflects light from the light-emitting elements, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be located on the reflective electrode layer RL in the third pixel PX3. The tenth insulating film INS10 may be formed of a silicon oxide (SiOx)-based inorganic film, but the present disclosure is not limited thereto.

The eleventh insulating film INS11 may be located on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, among light emitted from the light-emitting elements.

To match the resonance distance of the light emitted from the light-emitting elements in at least one of the first pixel PX1, the second pixel PX2, or the third pixel PX3, in some embodiments, the tenth insulating film INS10 and the eleventh insulating film INS11 may not be located under the first electrode AND of the first pixel PX1. The first electrode AND of the first pixel PX1 may be directly located on the reflective electrode layer RL. The eleventh insulating film INS11 may be located under the first electrode AND of the second pixel PX2. The tenth insulating film INS10 and the eleventh insulating film INS11 may be located under the first electrode AND of the third pixel PX3. Alternatively, respective thicknesses of the eleventh insulating film INS11 in the first to third pixels PX1, PX2, and PX3 may be adjusted to adjust the resonance distance.

In summary, the distance between the first electrode AND and the reflective electrode layer RL may be different in the first pixel PX1, the second pixel PX2, and the third pixel PX3. To adjust the distance from the reflective electrode layer RL to the second electrode CAT according to the main wavelength of the light emitted from each of the first pixel PX1, the second pixel PX2, and the third pixel PX3, the presence or absence of the tenth insulating film INS10 and the eleventh insulating film INS11 may be set in each of the first pixel PX1, the second pixel PX2, and the third pixel PX3. For example, it is illustrated in FIG. 5 that the distance between the first electrode AND and the reflective electrode layer RL in the third pixel PX3 is larger than the distance between the first electrode AND and the reflective electrode layer RL in the second pixel PX2, and is larger than the distance between the first electrode AND and the reflective electrode layer RL in the first pixel PX1. Also, the distance between the first electrode AND and the reflective electrode layer RL in the second pixel PX2 is larger than the distance between the first electrode AND and the reflective electrode layer RL in the first pixel PX1, but the present disclosure is not limited thereto.

In addition, although the tenth insulating film INS10 and the eleventh insulating film INS11 are illustrated in one or more embodiments, a twelfth insulating film located under the first electrode AND of the first pixel PX1 may be added in one or more embodiments. In this case, the eleventh insulating film INS11 and a twelfth insulating film may be located under the first electrode AND of the second pixel PX2, and the tenth insulating film INS10, the eleventh insulating film INS11, and the twelfth insulating film may be located under the first electrode AND of the third pixel PX3.

Each of the tenth vias VA10 may penetrate the tenth insulating film INS10 and/or the eleventh insulating film INS11 in the second pixel PX2 and the third pixel PX3, and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second pixel PX2 may be less than the thickness of the tenth via VA10 in the third pixel PX3.

The first electrode AND of each of the light-emitting elements may be located on the tenth insulating film INS10 and connected to the tenth via VA10. The first electrode AND of each of the light-emitting elements may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements may be titanium nitride (TiN).

The pixel-defining film PDL may be located on a part of the first electrode AND of each of the light-emitting elements. The pixel-defining film PDL may cover the edge of the first electrode AND of each of the light-emitting elements. The pixel-defining film PDL may serve to partition the first emission areas EA1, the second emission areas EA2, and the third emission areas EA3.

The first emission area EA1 may be defined as an area in which the first electrode AND, the light-emitting stack ES, and the second electrode CAT are sequentially stacked in the first pixel PX1 to emit light. The second emission area EA2 may be defined as an area in which the first electrode AND, the light-emitting stack ES, and the second electrode CAT are sequentially stacked in the second pixel PX2 to emit light. The third emission area EA3 may be defined as an area in which the first electrode AND, the light-emitting stack ES, and the second electrode CAT are sequentially stacked in the third pixel PX3 to emit light.

The pixel-defining film PDL may include first to third pixel-defining films PDL1, PDL2, and PDL3. The first pixel-defining film PDL1 may be located on the edge of the first electrode AND of each of the light-emitting elements, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed of a silicon oxide (SiOx)-based inorganic film, but the present disclosure is not limited thereto. The first pixel-defining film PDL1, the second pixel-defining film PDL2, and the third pixel-defining film PDL3 may each have a thickness of about 500 Å.

When the first pixel-defining film PDL1, the second pixel-defining film PDL2, and the third pixel-defining film PDL3 are formed as one pixel-defining film, the height of the one pixel-defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to reduce or prevent the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. For example, the width of the first pixel-defining film PDL1 may be greater than the width of the second pixel-defining film PDL2 and the width of the third pixel-defining film PDL3, and the width of the second pixel-defining film PDL2 may be greater than the width of the third pixel-defining film PDL3. The width of the first pixel-defining film PDL1 refers to the horizontal length of the first pixel-defining film PDL1 defined in the first direction DR1 and/or the second direction DR2.

Each of the plurality of trenches TRC may penetrate the first pixel-defining film PDL1, the second pixel-defining film PDL2, and the third pixel-defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be located between the neighboring pixels PX1, PX2, and PX3. Although FIG. 5 illustrates that two trenches TRC are located between adjacent pixels PX1, PX2, and PX3, the present disclosure is not limited thereto.

The light-emitting stack ES may include a plurality of stack layers. FIG. 5 illustrates that the light-emitting stack ES has a three-tandem structure including a first stack layer IL1, a second stack layer IL2, and a third stack layer IL3, but the present disclosure is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 that emit different lights. For example, the light-emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel-defining film PDL, and may be located on the bottom surface of each trench TRC. Due to the trench TRC, the first stack layer IL1 may be cut off between the neighboring pixels PX1, PX2, and PX3. The second stack layer IL2 may be located on the first stack layer IL1. Due to the trench TRC, the second stack layer IL2 may be cut off between the neighboring pixels PX1, PX2, and PX3. A cavity ESS, or an empty space, may be located between the first stack layer IL1 and the second stack layer IL2. The third stack layer IL3 may be located on the second stack layer IL2. The third stack layer IL3 is not cut off by the trench TRC, and may cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EMTL between the neighboring pixels PX1, PX2, and PX3. In addition, in the two-tandem structure, each of the trenches TRC may be a structure for cutting off the charge generation layer located between a lower intermediate layer and an upper intermediate layer, and the lower intermediate layer.

To stably cut off the first and second stack layers IL1 and IL2 of the display element layer EMTL between the neighboring pixels PX1, PX2, and PX, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. To cut off the first to third stack layers IL1, IL2, and IL3 of the display element layer EMTL between the neighboring pixels PX1, PX2, and PX3, another structure may exist instead of the trench TRC. For example, instead of the trench TRC, a reverse tapered partition wall may be located on the pixel-defining film PDL.

The number of the stack layers IL1, IL2, and IL3 that emit different lights is not limited to that shown in FIG. 5. For example, the light-emitting stack ES may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer for supplying electrons to one intermediate layer and supplying charges to the other intermediate layer may be located between the two intermediate layers.

In addition, FIG. 5 illustrates that the first to third stack layers IL1, IL2, and IL3 are all located in the first emission area EA1, the second emission area EA2, and the third emission area EA3, but the present disclosure is not limited thereto. For example, the first stack layer IL1 may be located in the first emission area EA1, and may be omitted from the second emission area EA2 and the third emission area EA3. Furthermore, the second stack layer IL2 may be located in the second emission area EA2, and may be omitted from the first emission area EA1 and the third emission area EA3. Further, the third stack layer IL3 may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO), such as ITO or IZO that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be located on the display element layer EMTL. The encapsulation layer TFE may include at least one inorganic film TFE1 and TFE2 to reduce or prevent oxygen or moisture from permeating into the display element layer EMTL. For example, the encapsulation layer TFE may include the first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed of titanium oxide (TiOx) or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

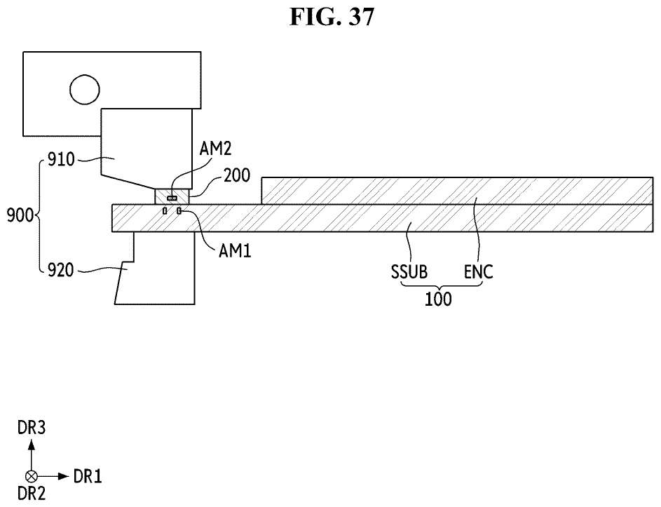

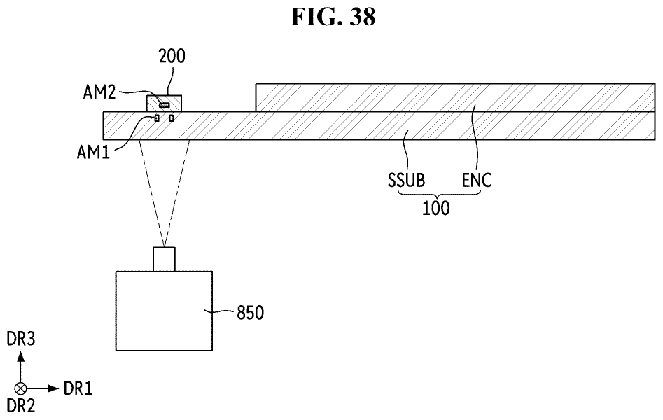

In accordance with one or more embodiments, an encapsulation substrate ENC (see FIGS. 37 and 38) may be further located on the encapsulation layer TFE. For example, the encapsulation substrate ENC may be located between the encapsulation layer TFE and the organic film APL. The encapsulation substrate ENC may include glass.

An organic film APL may be a layer for increasing the interfacial adhesion between the encapsulation layer TFE and the optical layer OPL. The organic film APL may be an organic film, such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the organic film APL.

The first color filter CF1 may overlap the first emission area EA1 of the first pixel PX1. The first color filter CF1 may transmit light of the first color (e.g., light of a blue wavelength band). The blue wavelength band may be about 370 nm to about 460 nm. Thus, the first color filter CF1 may transmit light of the first color among light emitted from the first emission area EA1.

The second color filter CF2 may overlap the second emission area EA2 of the second pixel PX2. The second color filter CF2 may transmit light of the second color (e.g., light of a green wavelength band). The green wavelength band may be about 480 nm to about 560 nm. Thus, the second color filter CF2 may transmit light of the second color among light emitted from the second emission area EA2.

The third color filter CF3 may overlap the third emission area EA3 of the third pixel PX3. The third color filter CF3 may transmit light of the third color (e.g., light of a red wavelength band). The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

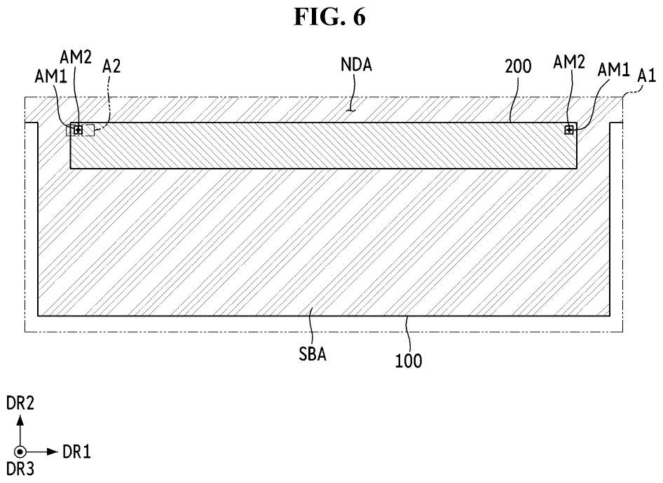

FIG. 6 is an enlarged view of area A1 of FIG. 2.

As shown in FIG. 6, a first alignment mark AM1 may be located at the display panel 100 and a second alignment mark AM2 may be located at the display driver 200. For example, two first alignment marks AM1 may be located at respective edges of the display panel 100, and two second alignment marks AM2 may be located at respective edges of the display driver 200. The first alignment marks AM1 may be located at the display panel 100 to face each other in the first direction DR1, and the second alignment marks AM2 may be displayed at the display driver 200 to face each other in the first direction DR1.

An alignment operation between the display panel 100 and the display driver 200 may be performed using the first alignment mark AM1 and the second alignment mark AM2. In this case, when the distance between the first alignment mark AM1 and the second alignment mark AM2 satisfies the tolerance, the display panel 100 and the display driver 200 may be determined to be aligned. For example, when the central portion of the first alignment mark AM1 and the central portion of the second alignment mark AM2 overlap each other, the display panel 100 and the display driver 200 may be determined to be aligned with each other.

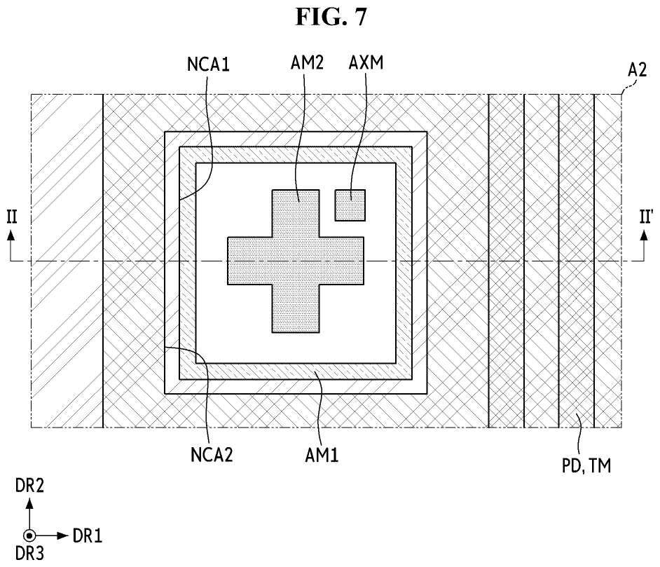

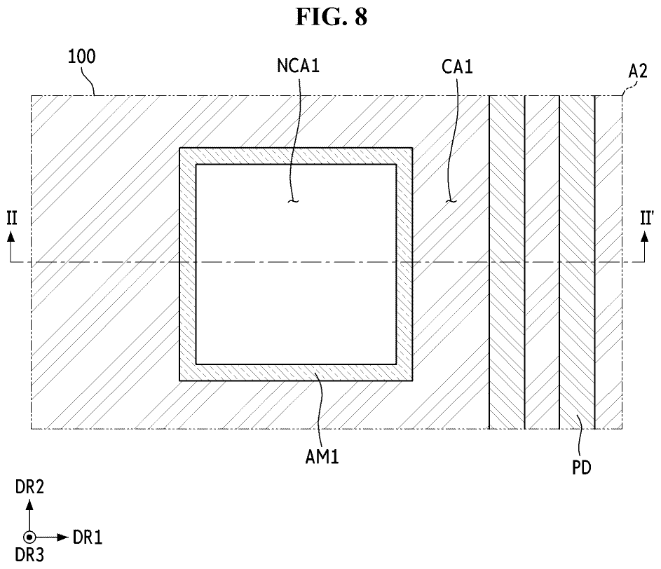

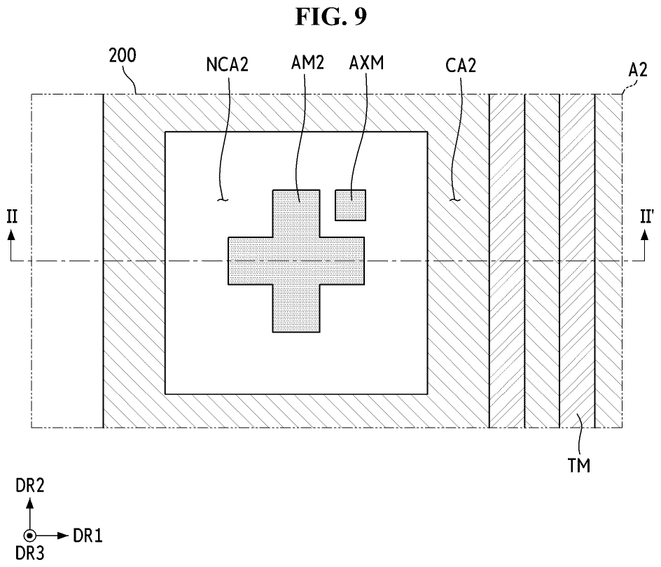

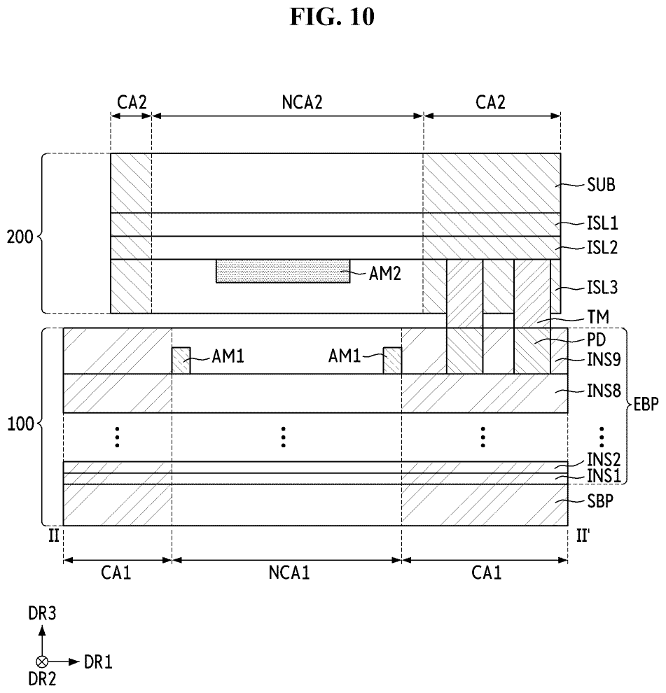

FIG. 7 is an enlarged view of area A2 of FIG. 6, FIG. 8 is a view selectively showing only the display panel 100, the first alignment mark AM1, and a pad PD in FIG. 7, FIG. 9 is a view selectively showing only the display driver 200, the second alignment mark AM2, and a terminal TM in FIG. 7, and FIG. 10 is a cross-sectional view taken along the line II-II′ of FIG. 7.

As shown in FIGS. 7 and 8, the display panel 100 (or the semiconductor substrate SSUB of the display panel 100) may include a first circuit area CA1 (or a first pattern area) where first circuit patterns, such as the pixel transistors PTR, the conductive layers ML1 to ML8, the vias VA1 to VA10, the reflective electrode layer RL, the first electrode AND, the light-emitting stack ES, and the second electrode CAT, which are described above, are located, and also may include a first non-circuit area NCA1 (or a first non-pattern area) where the above-described first circuit patterns are not located. In other words, at least one of the above-described first circuit patterns and the insulating films (e.g., the first to eleventh insulating films INS1 to INS11) may be located in the first circuit area CA1 of the display panel 100, and the insulating films may be located in the first non-circuit area NCA1 of the display panel 100. In accordance with one or more embodiments, in plan view shown in FIG. 8, the first non-circuit area NCA1 of the display panel 100 may have a quadrilateral shape. However, the shape of the first non-circuit area NCA1 of the display panel 100 is not limited thereto, and it may have various shapes.

As shown in FIGS. 7 and 8, the first alignment mark AM1 may be located in the aforementioned sub-region SBA (or pad area) of the display panel 100 (e.g., see FIG. 1 or 6). For example, the first alignment mark AM1 may be located in the first non-circuit area NCA1 of the display panel 100 in the sub-region SBA. In accordance with one or more embodiments, in plan view shown in FIG. 8, the first alignment mark AM1 may be located at the edge of the first non-circuit area NCA1 in the first non-circuit area NCA1. In plan view, the first alignment mark AM1 (e.g., the inner surface of the first alignment mark AM1) may have a closed curve shape surrounding a part of the first non-circuit area NCA1 in the first non-circuit area NCA1. In accordance with one or more embodiments, the outer surface of the first alignment mark AM1 may substantially surround the first non-circuit area NCA1. In other words, the outer surface of the first alignment mark AM1 may define the first non-circuit area NCA1. The first alignment mark AM1 may have a quadrilateral ring shape, as in the example shown in FIGS. 7 and 8. However, the shape of the first alignment mark AM1 is not limited thereto, and it may have various shapes. An insulating film, for example, may be located in the area surrounded by the first alignment mark AM1. For example, in plan view, the ninth insulating films INS9 may be partially located in the area surrounded by the first alignment mark AM1.

The first alignment mark AM1 may be made of a material containing metal. For example, the first alignment mark AM1 may be made of the same material as that of any one of the first to eighth conductive layers ML1 to ML8 described above. In accordance with one or more embodiments, the first alignment mark AM1 may be located on the eighth insulating film INS8, as shown in FIG. 10. For example, the first alignment mark AM1 may be made of the same material as the eighth conductive layer ML8.

The pad PD of the display panel 100 may be located in the first circuit area CA1 of the display panel 100. For example, the pad PD may be located in the first circuit area CA1 of the sub-region SBA (or pad area) of the display panel 100. In this case, a plurality of pads PD may be arranged close to the first alignment mark AM1. In accordance with one or more embodiments, the encapsulation layer TFE is not located in the sub-region SBA (or pad area) of the display panel 100 where the pad PD is located. The pad PD may be exposed to the outside through a through-hole of the insulating film (e.g., the ninth insulating film INS9).

As shown in FIGS. 7 and 9, the display driver 200 (or the substrate SUB of the display driver 200) may include a second circuit area CA2 (or a second pattern area) where second circuit patterns, such as transistors, conductive layers, and vias are located and a second non-circuit area NCA2 (or a second non-pattern area) where the above-described second circuit patterns are not located. In other words, at least one of the above-described second circuit patterns and insulating films ISL1, ISL2, and ISL3 (see FIG. 10) may be located in the second circuit area CA2 of the display driver 200, and the insulating films ISL1, ISL2, and ISL3 may be located in the second non-circuit area NCA2 of the display driver 200. In accordance with one or more embodiments, in plan view shown in FIG. 9, the second non-circuit area NCA2 of the display driver 200 may have a quadrilateral shape. However, the second non-circuit area NCA2 of the display driver 200 is not limited thereto and may have various shapes.

As shown in FIGS. 7 and 9, the display driver 200 may include the second alignment mark AM2. For example, the second alignment mark AM2 may be located in the second non-circuit area NCA2 of the display driver 200. In accordance with one or more embodiments, in plan view shown in FIG. 9, the second alignment mark AM2 may be located at the central portion of the second non-circuit area NCA2 in the second non-circuit area NCA2. For example, in plan view, the second alignment mark AM2 may occupy at least a part of the central portion of the second non-circuit area NCA2 in the second non-circuit area NCA2. The second alignment mark AM2 may have a cross shape, as in the example shown in FIGS. 7 and 9. However, the shape of the second alignment mark AM2 is not limited thereto and it may have various shapes.

In plan view shown in FIG. 9, the second alignment mark AM2 may be surrounded by the insulating film of the display driver 200. For example, in plan view, the second alignment mark AM2 may be surrounded by the third insulating film ISL3 of the display driver 200.

The second alignment mark AM2 may be made of a material containing metal. For example, the second alignment mark AM2 may be made of the same material as that of any one of the conductive layers of the display driver 200. In accordance with one or more embodiments, the second alignment mark AM2 may be located on the second insulating film ISL2, as shown in FIG. 10. For example, the second alignment mark AM2 may be made of the same material as the conductive layer of the display driver 200 located on the second insulating film ISL2 in the second circuit area CA2.

In accordance with one or more embodiments, an auxiliary alignment mark AXM may be further located at the display driver 200. For example, as shown in FIGS. 7 and 9, the auxiliary alignment mark AXM may be located in the second non-circuit area NCA2 adjacent to the first alignment mark AM1. The auxiliary alignment mark AXM may have a quadrilateral shape, as in the example shown in FIGS. 7 and 9. However, the shape of the auxiliary alignment mark AXM is not limited thereto, and may have various shapes in other embodiments. As shown in FIGS. 7 and 9, when the first alignment mark AM1 has a symmetrical shape in both an up-down direction and a left-right direction, the auxiliary alignment mark AXM may be located close to any one part of the first alignment mark AM1 so that the symmetry of the first alignment mark AM1 may be eliminated. Accordingly, the directionality of the first alignment mark AM1 may be easily detected and, thus, the directionality of the display driver 200 may be easily detected. The auxiliary alignment mark AXM may be omitted.

The terminal TM (e.g., bump) of the display driver 200 may be located in the second circuit area CA2 of the display driver 200. In this case, a plurality of terminals TM may be arranged close to the second alignment mark AM2. As shown in FIG. 10, the terminals TM of the display driver 200 may protrude to the outside through the through-hole of the insulating film (e.g., the third insulating film ISL3). The terminals TM of the display driver 200 may respectively overlap the pads PD of the display panel 100. The terminals TM of the display driver 200 may be respectively connected to the pads PD of the display panel 100. For example, the terminals TM of the display driver 200 and the pads PD of the display panel 100 may be electrically connected to each other by an anisotropic conductive film located therebetween.

In accordance with one or more embodiments, in plan view shown in FIG. 7, a region (hereinafter, referred to as an inner region of the first alignment mark AM1) surrounded and defined by the first alignment mark AM1 may have an area that is larger than that of the second alignment mark AM2. For example, the area of the inner region of the first alignment mark AM1 may be larger than that of the second alignment mark AM2. In accordance with one or more embodiments, when the above-described auxiliary alignment mark AXM is further located at the display driver 200, in plan view shown in FIG. 7, the inner region of the first alignment mark AM1 may have an area that is larger than those of the second alignment mark AM2 and the auxiliary alignment mark AXM. For example, the area of the inner region of the first alignment mark AM1 may be larger than the sum of the area of the second alignment mark AM2 and the area of the auxiliary alignment mark AXM.

In accordance with one or more embodiments, in plan view shown in FIG. 7, the first alignment mark AM1 may surround the second alignment mark AM2. For example, in plan view, the second alignment mark AM2 may be located in the inner region of the first alignment mark AM1. In accordance with one or more embodiments, when the above-described auxiliary alignment mark AXM is further located at the display driver 200, in plan view, the first alignment mark AM1 may surround the second alignment mark AM2 and the auxiliary alignment mark AXM. For example, in plan view, the second alignment mark AM2 and the auxiliary alignment mark AXM may be located in the inner region of the first alignment mark AM1.

In accordance with one or more embodiments, in plan view shown in FIG. 7, the second non-circuit area NCA2 of the display driver 200 may have an area that is larger than that of the first non-circuit area NCA1 of the display panel 100. In other words, the area of the second non-circuit area NCA2 may be larger than that of the first non-circuit area NCA1. In plan view, the edge of the second non-circuit area NCA2 may surround the first non-circuit area NCA1. For example, the entire first non-circuit area NCA1 may be overlapped by the second non-circuit area NCA2.

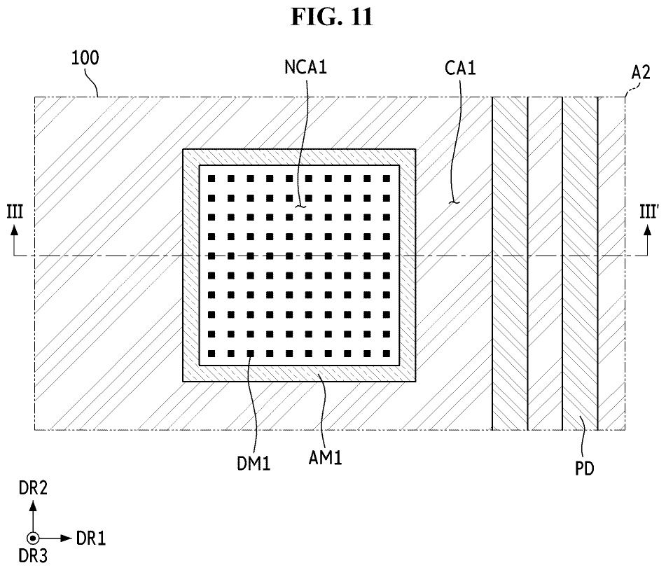

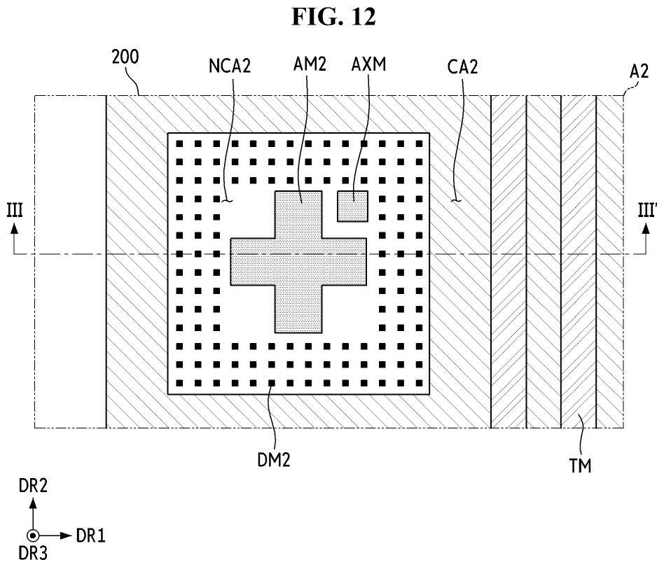

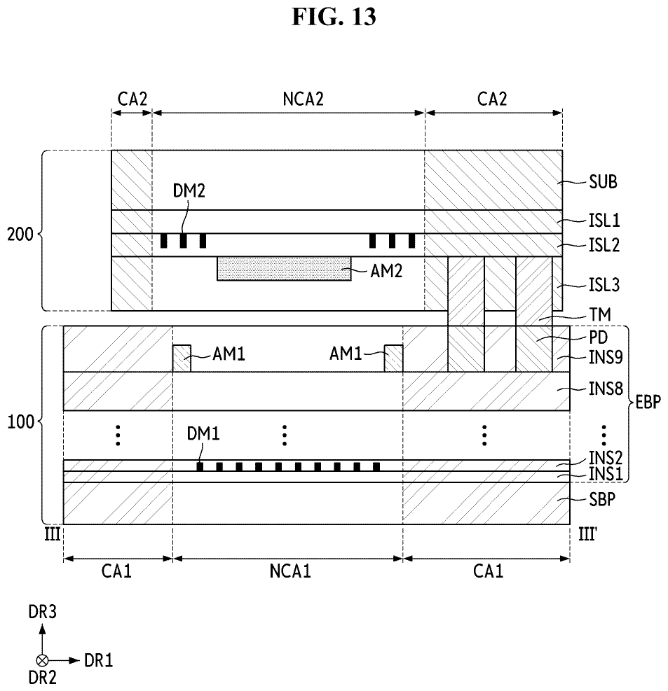

FIG. 11 is a plan view of the display panel 100 according to one or more embodiments, FIG. 12 is a plan view of the display driver 200 according to one or more embodiments, and FIG. 13 is a cross-sectional view taken along the line III-III′ of FIGS. 11 and 12 when the display panel 100 of FIG. 11 and the display driver 200 of FIG. 12 are connected to each other.

The display device of FIGS. 11 to 13 is different from the display device of FIGS. 8 and 9 described above in that it further includes a first dummy pattern DM1 and a second dummy pattern DM2, and the difference will be mainly described as follows.

As shown in FIGS. 11 and 13, the first dummy patterns DM1 may be located in the first non-circuit area NCA1 of the display panel 100. In plan view shown in FIG. 11, the first dummy patterns DM1 may be surrounded by the first alignment mark AM1. For example, the first dummy patterns DM1 may be located in the inner region of the first alignment mark AM1.

The first dummy patterns DM1 may be arranged in a matrix form along the first direction DR1 and the second direction DR2. The gap between adjacent first dummy patterns DM1 may be the same.

The first dummy patterns DM1 may have the same shape. For example, in plan view, each of the first dummy patterns DM1 may have a quadrilateral shape. However, the shape of the first dummy patterns DM1 is not limited thereto and it may have various shapes.

The first dummy pattern DM1 may be made of a material containing metal. For example, the first dummy pattern DM1 may be made of the same material as that of any one of the first to eighth conductive layers ML1 to ML8 described above. In accordance with one or more embodiments, the first dummy pattern DM1 may be located on the first insulating film INS1, as shown in FIG. 13. For example, the first dummy pattern DM1 may be made of the same material as that of the first conductive layer ML1.

In accordance with one or more embodiments, the first dummy pattern DM1 and the first alignment mark AM1 may be located on different layers. For example, the first dummy pattern DM1 may be located closer to the substrate (e.g., the semiconductor substrate SSUB) than the first alignment mark AM1. As an example, the distance between the first dummy pattern DM1 and the semiconductor backplane SBP (e.g., the semiconductor substrate SSUB) may be less than the distance between the first alignment mark AM1 and the semiconductor backplane SBP (e.g., the semiconductor substrate SSUB).

The first dummy pattern DM1 may reduce or minimize the stepped portion between the insulating films (e.g., the second to ninth insulating films INS2 to INS9) of the first circuit area CA1 and the insulating films (e.g., the second to ninth insulating films INS2 to INS9) of the first non-circuit area NCA1. For example, because the first non-circuit area NCA1 does not include the first circuit patterns of the first circuit area CA1, the insulating films of the first non-circuit area NCA1 may have a height that is lower than that of the insulating film of the first circuit area CA1, and the above-described first dummy patterns DM1 may be located in the first non-circuit area NCA1 to reduce or minimize the stepped portion between the insulating films of the first circuit area CA1 and the insulating films of the first non-circuit area NCA1. Accordingly, the stepped portion between the first alignment mark AM1 located above the first dummy pattern DM1 and its neighboring conductive layer (e.g., the eighth conductive layer ML8) may be reduced or minimized.

Meanwhile, the first dummy pattern DM1 may overlap the first alignment mark AM1. For example, in FIG. 13, the first dummy pattern DM1 may be further between the first alignment mark AM1 and the first insulating film INS1 so that the first dummy pattern DM1 and the first alignment mark AM1 overlap each other.

As shown in FIGS. 12 and 13, the second dummy patterns DM2 may be located in the second non-circuit area NCA2 of the display driver 200. In plan view shown in FIG. 12, the second dummy patterns DM2 may be surrounded by the second non-circuit area NCA2.

The second dummy patterns DM2 may be arranged in a matrix form along the first direction DR1 and the second direction DR2. The gap between adjacent second dummy patterns DM2 may be the same.

The second dummy patterns DM2 may have the same shape. For example, in plan view, each of the second dummy patterns DM2 may have a quadrilateral shape. However, the shape of the second dummy patterns DM2 is not limited thereto and it may have various shapes.

The second dummy pattern DM2 may be made of a material containing metal. For example, the second dummy pattern DM2 may be made of the same material as that of any one of the conductive layers of the display driver 200. In accordance with one or more embodiments, the second dummy pattern DM2 may be located on the first insulating film ISL1, as shown in FIG. 13. For example, the second dummy pattern DM2 may be made of the same material as that of the conductive layer on the first insulating film ISL1 of the display driver 200.

In accordance with one or more embodiments, the second dummy pattern DM2 and the second alignment mark AM2 may be located on different layers. For example, the second dummy pattern DM2 may be located closer to the substrate SUB of the display driver 200 than the second alignment mark AM2. As an example, the distance between the second dummy pattern DM2 and the substrate SUB may be less than the distance between the second alignment mark AM2 and the substrate SUB.

The second dummy pattern DM2 may reduce or minimize the stepped portion between the insulating films (e.g., the second and third insulating films ISL2 and ISL3) of the second circuit area CA2 and the insulating films (e.g., the second and third insulating films ISL2 and ISL3) of the second non-circuit area NCA2. For example, because the second non-circuit area NCA2 does not include the second circuit patterns of the second circuit area CA2, the insulating films of the second non-circuit area NCA2 may have a height that is lower than that of the insulating film of the second circuit area CA2, and the above-described second dummy patterns DM2 may be located in the second non-circuit area NCA2 to reduce or minimize the stepped portion between the insulating films of the second circuit area CA2 and the insulating films of the second non-circuit area NCA2. Accordingly, the stepped portion between the second alignment mark AM2 located above the second dummy pattern DM2 and its neighboring conductive layer (e.g., the conductive layer on the first insulating film ISL1) may be reduced or minimized.

Meanwhile, the second dummy pattern DM2 may overlap the second alignment mark AM2. For example, in FIG. 13, the second dummy pattern DM2 may be further located between the second alignment mark AM2 and the first insulating film ISL1 so that the second dummy pattern DM2 and the second alignment mark AM2 overlap each other.

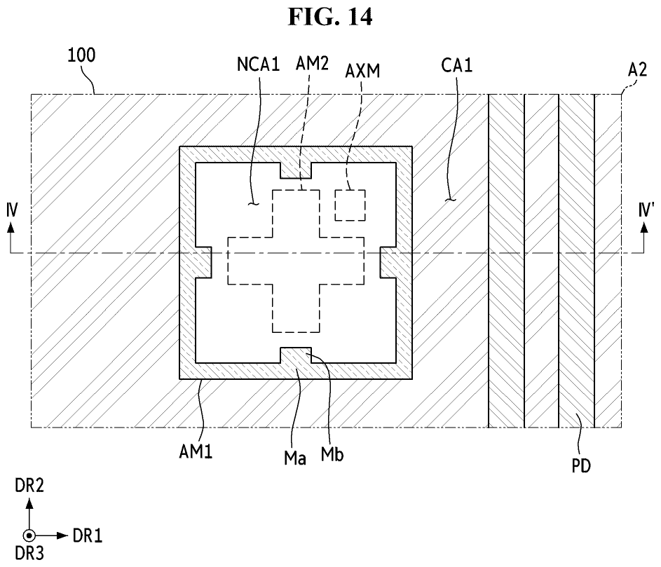

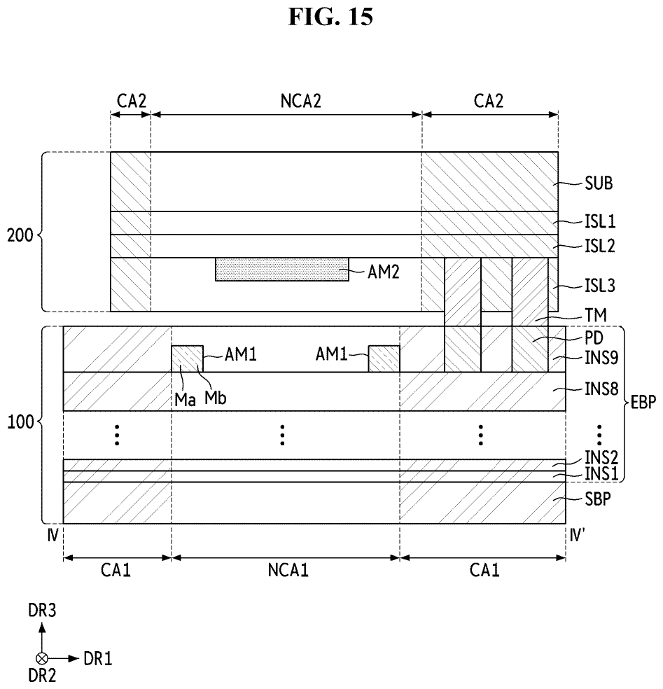

FIG. 14 is a plan view of the display panel 100 according to one or more embodiments, and FIG. 15 is a cross-sectional view taken along the line IV-IV′ of FIG. 14 when the display panel 100 of FIG. 14 and the display driver 200 of FIG. 9 are connected to each other.

The display device of FIGS. 14 and 15 is different from the display device of FIGS. 8 and 10 described above in the shape of the first alignment mark AM1, and this difference will be mainly described as follows.

As shown in FIGS. 14 and 15, the first alignment mark AM1 of the display panel 100 may include an outer pattern Ma and a protrusion pattern Mb.

Because the outer pattern Ma is the same as the above-described first alignment mark AM1, the description of the outer pattern Ma refers to the description of the first alignment mark AM1 of FIG. 8 described above.

The protrusion pattern Mb may protrude from the inner surface of the outer pattern Ma. For example, the protrusion patterns Mb respectively protruding from the two surfaces facing each other in the first direction DR1 of the outer pattern Ma may protrude toward each other from the central portions of the respective surfaces to face each other in the first direction DR1. Further, the protrusion patterns Mb respectively protruding from the two surfaces facing each other in the second direction DR2 of the outer pattern Ma may protrude toward each other from the central portions of the respective surfaces to face each other in the second direction DR2.

In plan view, the protrusion patterns Mb may not overlap the second alignment mark AM2 and the auxiliary alignment mark AXM.

The outer pattern Ma and the protrusion pattern Mb may be formed integrally with each other.

The outer pattern Ma and the protrusion pattern Mb may be made of the same material. The outer pattern Ma and the protrusion pattern Mb may be made of the same material as that of the eighth conductive layer ML8, as in the example shown FIG. 15.

When the outer pattern Ma and the protrusion pattern Mb are made of different materials, the outer pattern Ma and the protrusion pattern Mb may be located on different layers. For example, the outer pattern Ma may be made of the same material as the eighth conductive layer ML8, and the protrusion pattern Mb may be made of the same material as the seventh conductive layer ML7.

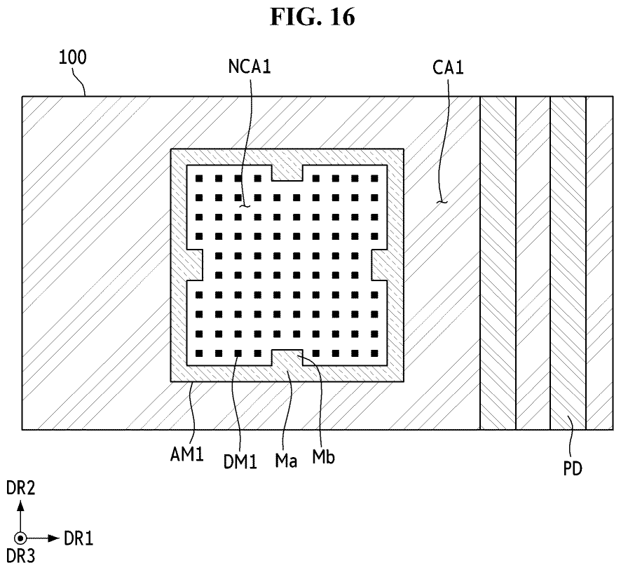

FIG. 16 is a plan view of the display panel 100 according to one or more embodiments.

The display panel 100 of FIG. 16 is different from the display device of FIGS. 14 and 15 described above in that it further includes the first dummy pattern DM1, and the difference will be mainly described as follows.

As shown in FIG. 16, the display panel 100 according to one or more embodiments may include the first alignment mark AM1 and the first dummy pattern DM1. Here, the first alignment mark AM1 may include the outer pattern Ma and the protrusion pattern Mb described above.

Because the first dummy pattern DM1 of FIG. 16 is the same as the first dummy pattern DM1 of FIGS. 11 and 13 described above, the description of the first dummy pattern DM1 of FIG. 16 refers to the description of the first dummy pattern DM1 of FIGS. 11 and 13.

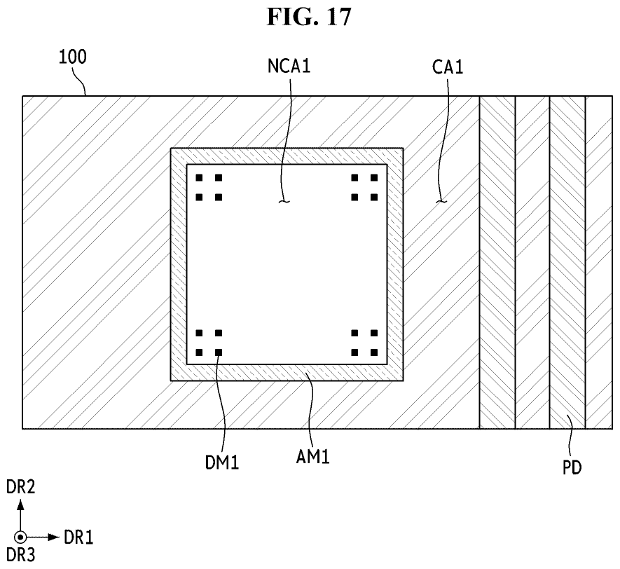

FIG. 17 is a plan view of the display panel 100 according to one or more embodiments.

The display panel 100 of FIG. 17 is different from the display panel 100 of FIG. 11 described above in the arrangement position of the first dummy pattern DM1, and the difference will be mainly described as follows.

In plan view shown in FIG. 17, the first dummy patterns DM1 may be located close to each corner of the first alignment mark AM1 in the inner region of the first alignment mark AM1. For example, the first dummy patterns DM1 may not be located at the central portion of the inner region of the first alignment mark AM1.

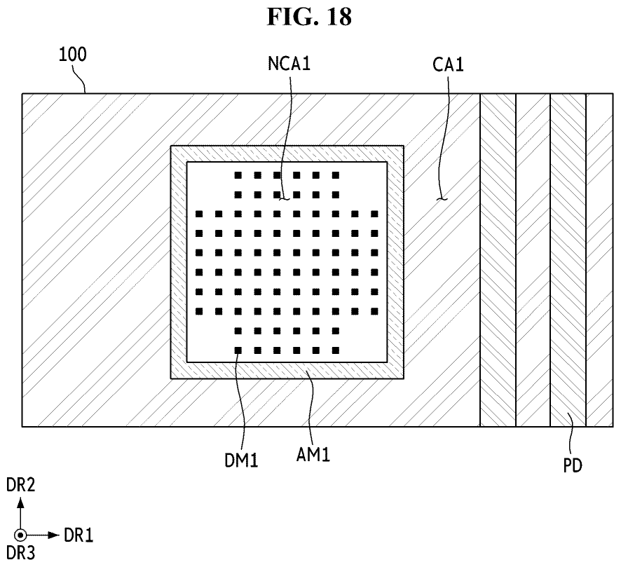

FIG. 18 is a plan view of the display panel 100 according to one or more embodiments.

The display panel 100 of FIG. 18 is different from the display panel 100 of FIG. 11 described above in the arrangement position of the first dummy pattern DM1, and the difference will be mainly described as follows.

In plan view shown in FIG. 18, the first dummy patterns DM1 may be located in a region except each corner of the first alignment mark AM1 in the inner region of the first alignment mark AM1.

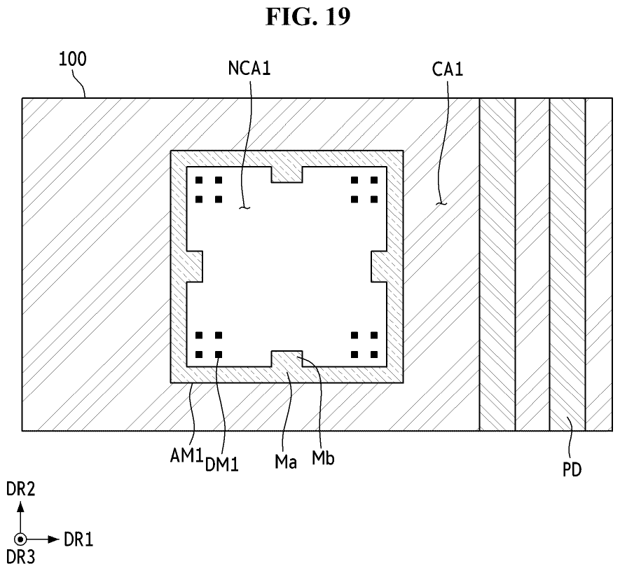

FIG. 19 is a plan view of the display panel 100 according to one or more embodiments.

The display panel 100 of FIG. 19 is different from the display panel 100 of FIG. 16 described above in the arrangement position of the first dummy pattern DM1, and the difference will be mainly described as follows.

In plan view shown in FIG. 19, the first dummy patterns DM1 may be located close to each corner of the first alignment mark AM1 in the inner region of the first alignment mark AM1. For example, the first dummy patterns DM1 may not be located at the central portion of the inner region of the first alignment mark AM1.

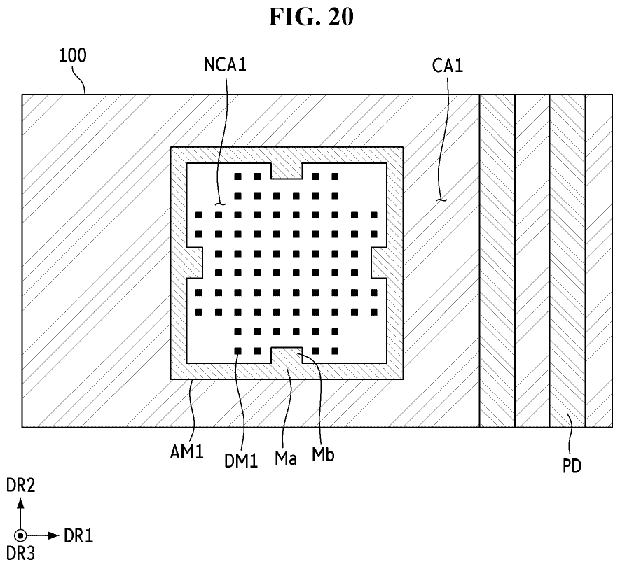

FIG. 20 is a plan view of the display panel 100 according to one or more embodiments.

The display panel 100 of FIG. 20 is different from the display panel 100 of FIG. 16 described above in the arrangement position of the first dummy pattern DM1, and the difference will be mainly described as follows.

In plan view shown in FIG. 20, the first dummy patterns DM1 may be located in a region except each corner of the first alignment mark AM1 in the inner region of the first alignment mark AM1.

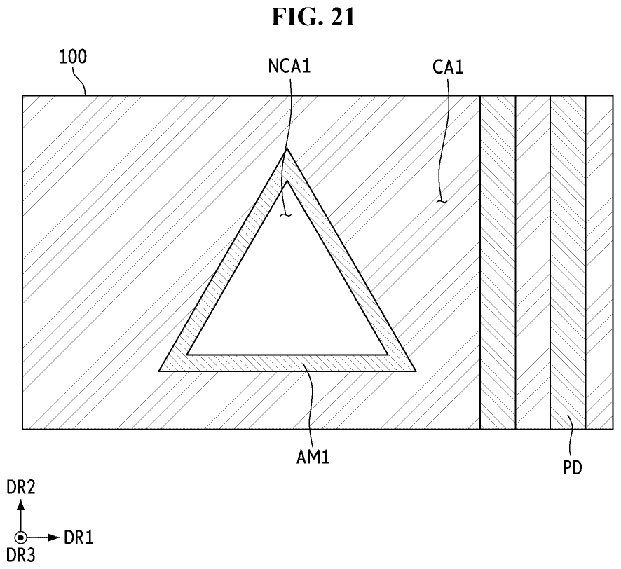

FIG. 21 is a plan view of the display panel 100 according to one or more embodiments.

The display panel 100 of FIG. 21 is different from the display panel 100 of FIG. 8 described above in the shape of the first alignment mark AM1, and the difference will be mainly described as follows.

In plan view shown in FIG. 21, the first alignment mark AM1 may have a triangular shape. For example, in plan view, the first alignment mark AM1 may have a closed curve shape surrounding a part of the first non-circuit area NCA1, and the closed curve may form a triangular shape.

Further, in plan view shown in FIG. 21, the first non-circuit area NCA1 may have a triangular shape.

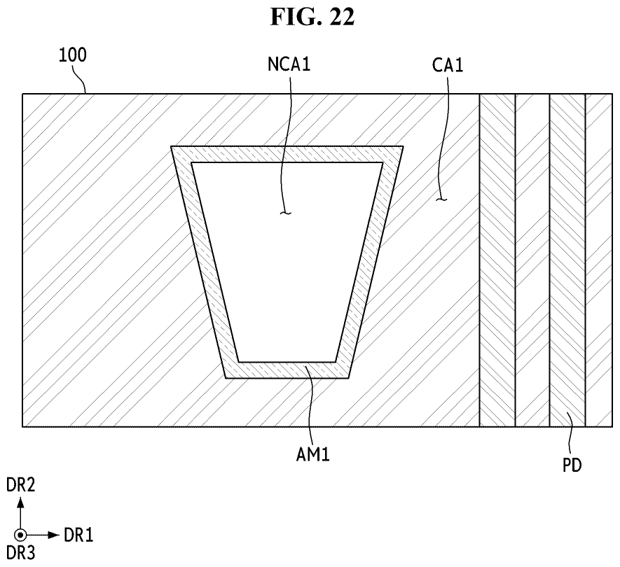

FIG. 22 is a plan view of the display panel 100 according to one or more embodiments.

The display panel 100 of FIG. 22 is different from the display panel 100 of FIG. 8 described above in the shape of the first alignment mark AM1, and the difference will be mainly described as follows.

In plan view shown in FIG. 22, the first alignment mark AM1 may have a trapezoidal (or inverted trapezoidal) shape. For example, in plan view, the first alignment mark AM1 may have a closed curve shape surrounding a part of the first non-circuit area NCA1, and the closed curve may form a trapezoidal (or inverted trapezoidal) shape.

Further, in plan view shown in FIG. 22, the first non-circuit area NCA1 may have a trapezoidal (or inverted trapezoidal) shape.

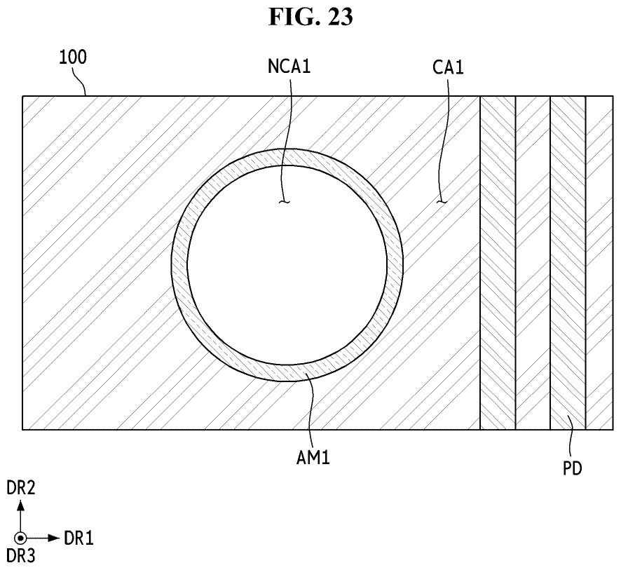

FIG. 23 is a plan view of the display panel 100 according to one or more embodiments.

The display panel 100 of FIG. 23 is different from the display panel 100 of FIG. 18 described above in the shape of the first alignment mark AM1, and the difference will be mainly described as follows.

In plan view shown in FIG. 23, the first alignment mark AM1 may have a circular shape. For example, in plan view, the first alignment mark AM1 may have a closed curve shape surrounding a part of the first non-circuit area NCA1, and the closed curve may form a circular shape.

Further, in plan view shown in FIG. 23, the first non-circuit area NCA1 may have a circular shape.

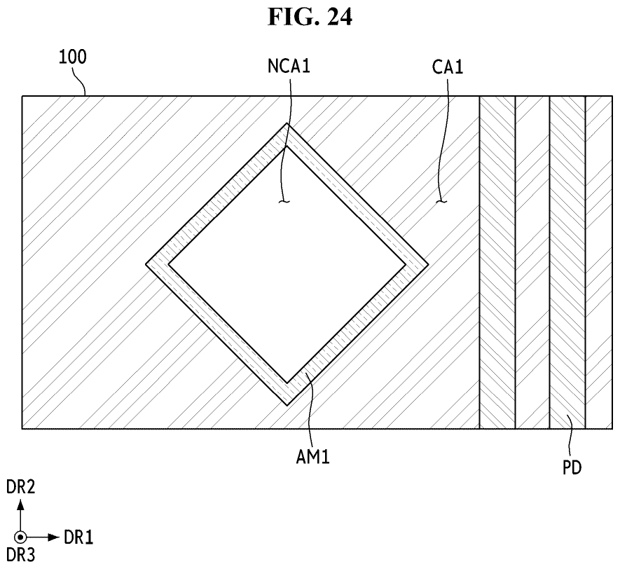

FIG. 24 is a plan view of the display panel 100 according to one or more embodiments.

The display panel 100 of FIG. 24 is different from the display panel 100 of FIG. 8 described above in the shape of the first alignment mark AM1, and the difference will be mainly described as follows.

In plan view shown in FIG. 24, the first alignment mark AM1 may have a rhombic shape. For example, in plan view, the first alignment mark AM1 may have a closed curve shape surrounding a part of the first non-circuit area NCA1, and the closed curve may form a rhombic shape.

Further, in plan view shown in FIG. 24, the first non-circuit area NCA1 may have a rhombic shape.

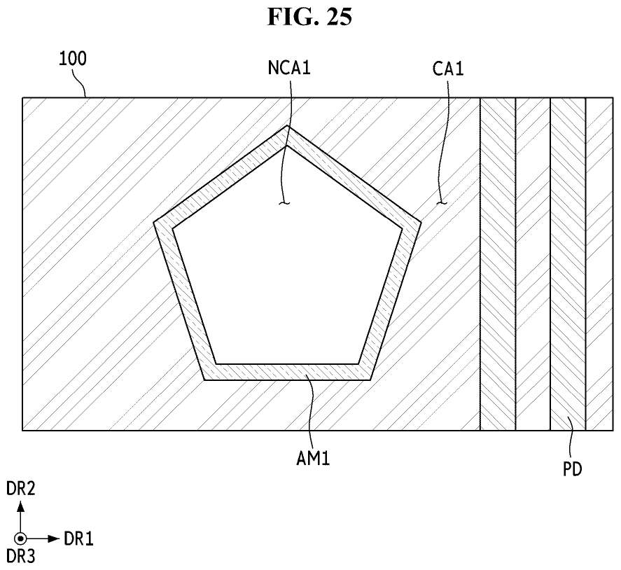

FIG. 25 is a plan view of the display panel 100 according to one or more embodiments.

The display panel 100 of FIG. 25 is different from the display panel 100 of FIG. 8 described above in the shape of the first alignment mark AM1, and the difference will be mainly described as follows.

In plan view shown in FIG. 25, the first alignment mark AM1 may have a pentagonal shape. For example, in plan view, the first alignment mark AM1 may have a closed curve shape surrounding a part of the first non-circuit area NCA1, and the closed curve may form a pentagonal shape.

Further, in plan view shown in FIG. 25, the first non-circuit area NCA1 may have a pentagonal shape.

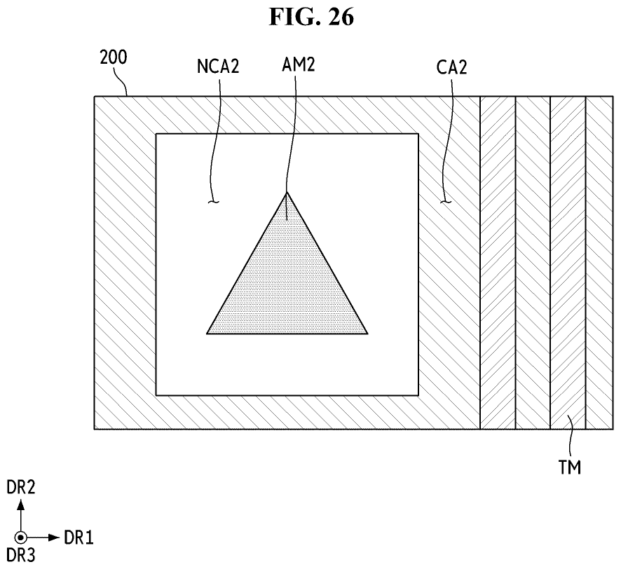

FIG. 26 is a plan view of the display driver 200 according to one or more embodiments.

The display driver 200 of FIG. 26 is different from the display panel 100 of FIG. 9 described above in the shape of the second alignment mark AM2, and the difference will be mainly described as follows.

In plan view shown in FIG. 26, the second alignment mark AM2 may have a triangular shape.

Meanwhile, the display driver 200 of FIG. 26 may further include the auxiliary alignment mark AXM of FIG. 9 described above.

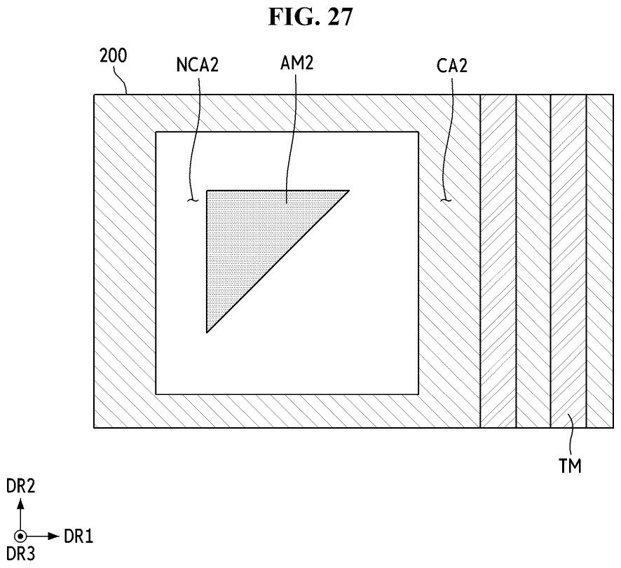

FIG. 27 is a plan view of the display driver 200 according to one or more embodiments.

The display driver 200 of FIG. 27 is different from the display panel 100 of FIG. 9 described above in the shape of the second alignment mark AM2, and the difference will be mainly described as follows.

In plan view shown in FIG. 27, the second alignment mark AM2 may have a right-angled triangular shape.

Meanwhile, the display driver 200 of FIG. 27 may further include the auxiliary alignment mark AXM of FIG. 9 described above.

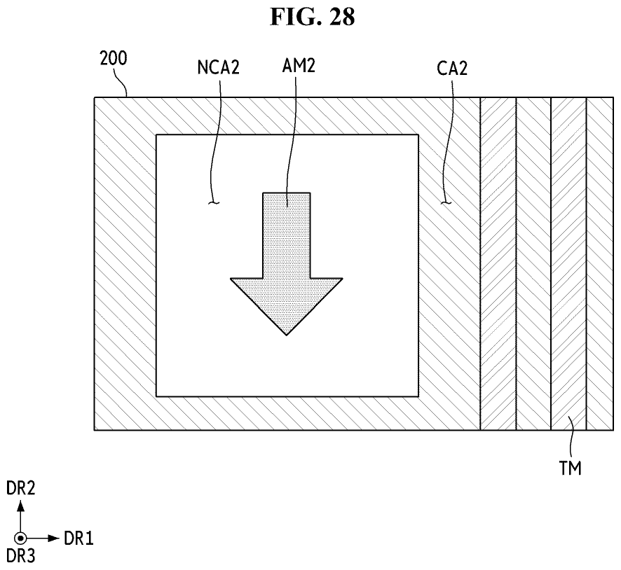

FIG. 28 is a plan view of the display driver 200 according to one or more embodiments.

The display driver 200 of FIG. 28 is different from the display panel 100 of FIG. 9 described above in the shape of the second alignment mark AM2, and the difference will be mainly described as follows.

In plan view shown in FIG. 28, the second alignment mark AM2 may have an arrow shape.

Meanwhile, the display driver 200 of FIG. 28 may further include the auxiliary alignment mark AXM of FIG. 9 described above.

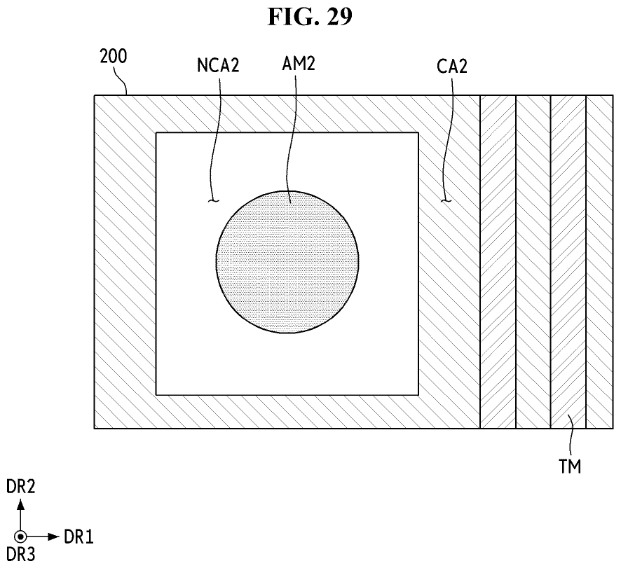

FIG. 29 is a plan view of the display driver 200 according to one or more embodiments.

The display driver 200 of FIG. 29 is different from the display panel 100 of FIG. 9 described above in the shape of the second alignment mark AM2, and the difference will be mainly described as follows.

In plan view shown in FIG. 29, the second alignment mark AM2 may have a circular shape.

Meanwhile, the display driver 200 of FIG. 29 may further include the auxiliary alignment mark AXM of FIG. 9 described above.

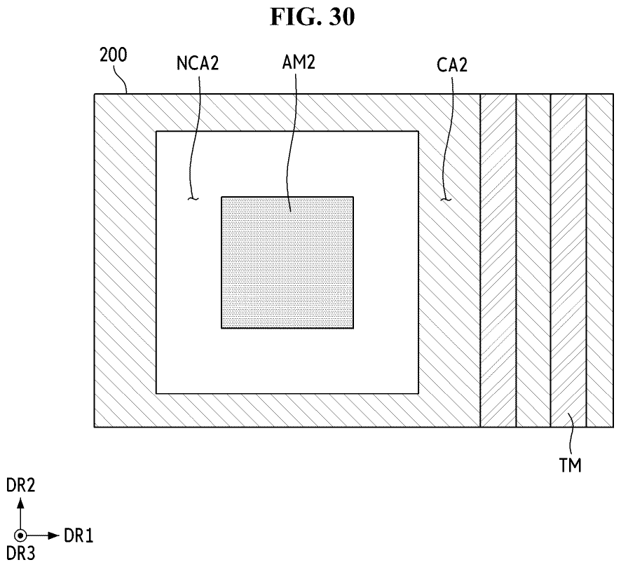

FIG. 30 is a plan view of the display driver 200 according to one or more embodiments.

The display driver 200 of FIG. 30 is different from the display panel 100 of FIG. 9 described above in the shape of the second alignment mark AM2, and the difference will be mainly described as follows.

In plan view shown in FIG. 30, the second alignment mark AM2 may have a quadrilateral shape.

Meanwhile, the display driver 200 of FIG. 30 may further include the auxiliary alignment mark AXM of FIG. 9 described above.

In accordance with one or more embodiments, the display panel 100 may have any one of the first alignment marks AM1 shown in FIGS. 8 and 21 to 25, and the display driver 200 may have any one of the second alignment marks AM2 shown in FIGS. 9 and 26 to 30.

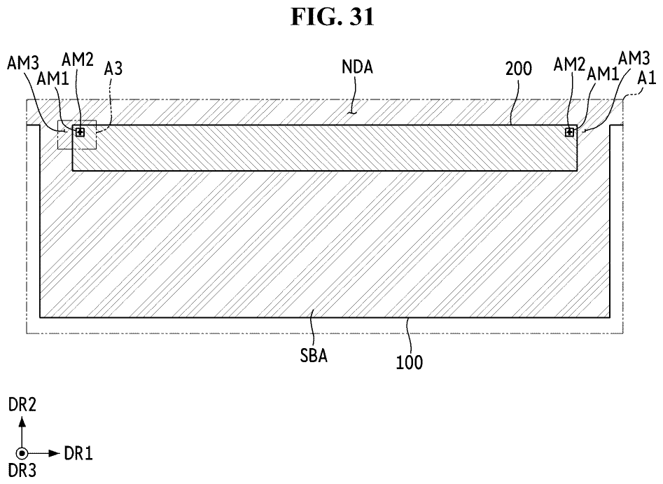

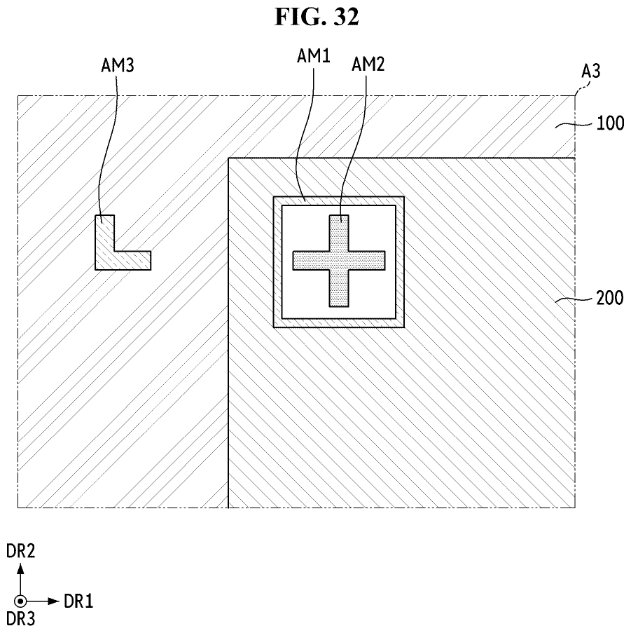

FIG. 31 is an enlarged view of area A1 of FIG. 2 according to one or more other embodiments, and FIG. 32 is an enlarged view of area A3 of FIG. 31.

The display device of FIG. 31 differs from the display device of FIG. 6 in that it further includes a third alignment mark AM3. The following description will mainly focus on this difference.

The display device of one or more embodiments may further include the third alignment mark AM3, as shown in FIGS. 31 and 32.

The third alignment mark AM3 may be located in the sub-region SBA (or pad area) of the display panel 100. For example, when a plurality of third alignment marks AM3 are provided, one third alignment mark AM3 may be located between one edge of the display driver 200 and one edge of the display panel 100, and another third alignment mark AM3 may be located between the other edge of the display driver 200 and the other edge of the display panel 100.

The third alignment mark AM3 may be located adjacent to the first alignment mark AM1. For example, when the plurality of third alignment marks AM3 are provided, one third alignment mark AM3 may be located adjacent to the first alignment mark AM1 overlapping one edge of the display driver 200, and another third alignment mark AM3 may be located adjacent to the first alignment mark AM1 overlapping the other edge of the display driver 200.

The alignment operation between the display panel 100 and the display driver 200 may be performed using the first alignment mark AM1, the second alignment mark AM2, and the third alignment mark AM3. In this case, the alignment state between the display panel 100 and the display driver 200 may be determined based on the distance between the third alignment mark AM3 of the display panel 100 and the second alignment mark AM2 of the display driver 200. For example, when the distance between one edge of the third alignment mark AM3 and the central portion of the second alignment mark AM2 satisfies the tolerance, it may be determined that the display panel 100 and the display driver 200 are aligned with each other.

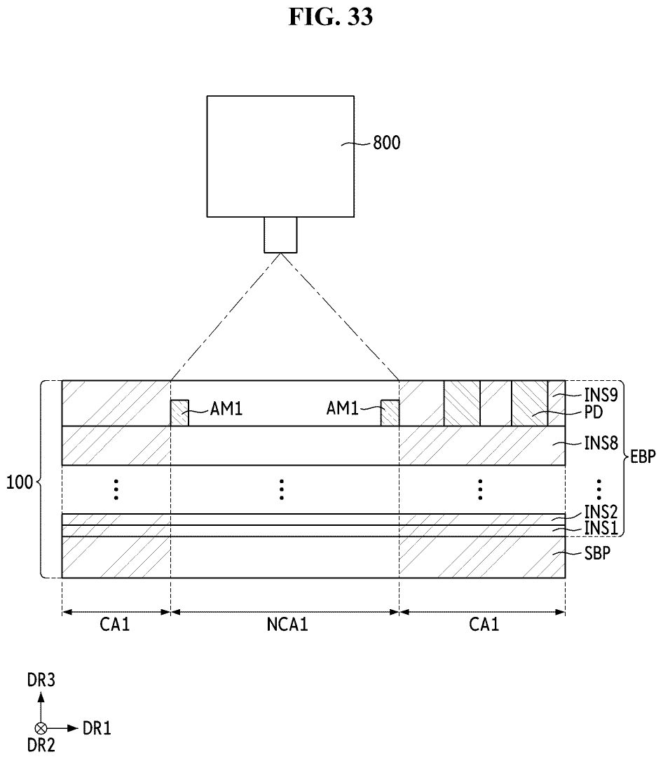

FIGS. 33 to 39 are views illustrating a method of manufacturing a display device according to one or more embodiments.

First, as shown in FIG. 33, the first alignment marks AM1 of the display panel 100 may be imaged by an imaging device 800. For example, when the display panel 100 includes two first alignment marks AM1, the respective first alignment marks AM1 may be sequentially imaged. Here, the imaging device 800 may be, for example, a camera. In accordance with one or more embodiments, the imaging device 800 may be above the top surface (e.g., a surface distant from the semiconductor substrate SSUB) of the display panel 100, and may image the first alignment mark AM1 of the display panel 100. However, the present disclosure is not limited thereto, and the imaging device 800 may be below the bottom surface (e.g., the bottom surface of the semiconductor substrate SSUB) of the display panel 100, and may image the first alignment mark AM1 of the display panel 100, for example.

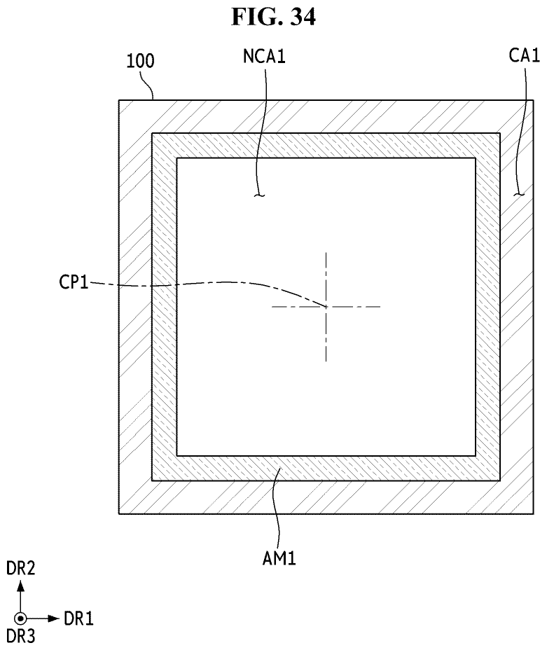

Next, as shown in FIG. 34, coordinates of a central portion CP1 of the first alignment mark AM1 may be calculated. For example, the coordinates of the central portion CP1 of the first alignment mark AM1 located on one side of the display panel 100, and the coordinates of the central portion CP1 of the first alignment mark AM1 located on the other side of the display panel 100, may be calculated. Next, the coordinates of the midpoint of the line segment, which connects the central portion CP1 of the first alignment mark AM1 located on one side of the display panel 100 and the central portion CP1 of the first alignment mark AM1 located on the other side of the display panel 100, may be calculated. In other words, the coordinates (hereinafter, referred to as first coordinates) of the central portion of the imaginary line segment that connects the central portions of the first alignment marks AM1 may be calculated.

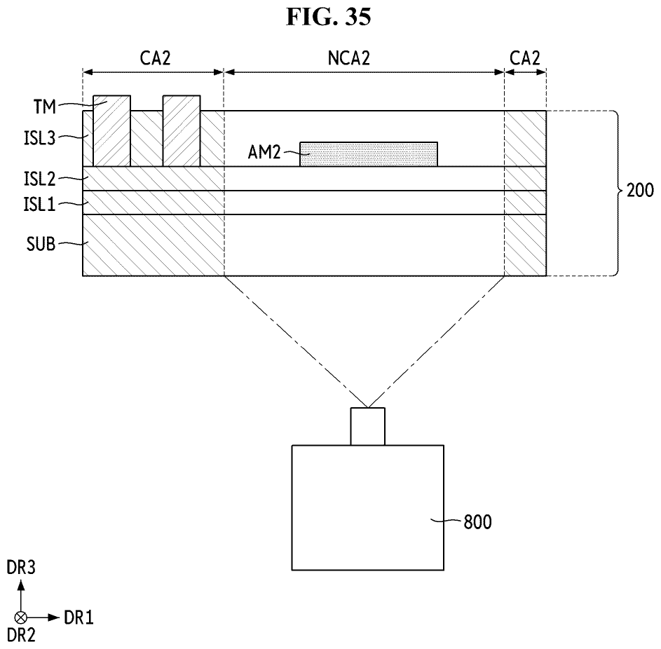

Next, as shown in FIG. 35, the second alignment marks AM2 of the display driver 200 may be imaged by the imaging device 800. For example, when the display driver 200 includes two second alignment marks AM2, the respective second alignment marks AM2 may be sequentially imaged. In this case, the auxiliary alignment mark AXM may also be imaged together. In accordance with one or more embodiments, the imaging device 800 may be located on, or below, the bottom surface (e.g., the bottom surface of the substrate SUB) of the display driver 200, and may image the second alignment mark AM2 of the display driver 200. However, the present disclosure is not limited thereto, and the imaging device 800 may be located on, or above, the top surface (e.g., the surface distant from the substrate SUB) of the display driver 200, and may image the second alignment mark AM2 of the display driver 200.

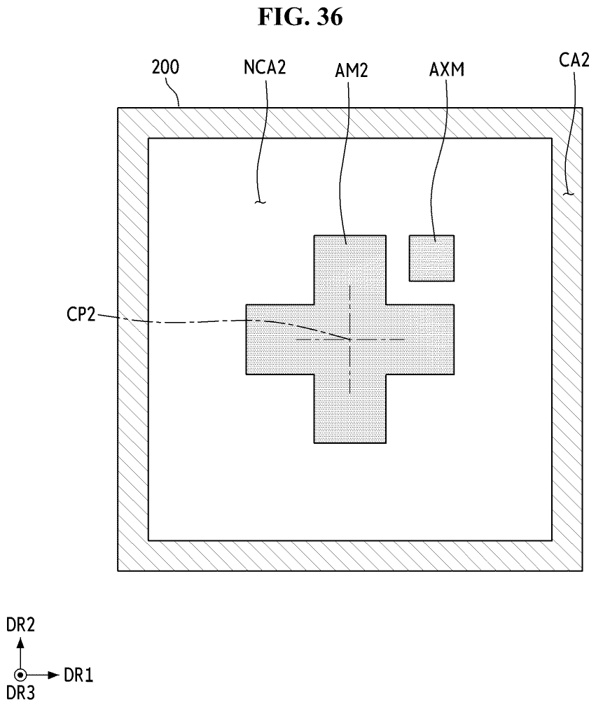

Next, as shown in FIG. 36, the coordinates of the central portion of the second alignment mark AM2 may be calculated. For example, the coordinates of the central portion of the second alignment mark AM2 located on one side of the display driver 200, and the coordinates of the central portion CP2 of the second alignment mark AM2 located on the other side of the display driver 200, may be calculated. Next, the coordinates of the midpoint of the line segment, which connects the central portion CP2 of the second alignment mark AM2 located on one side of the display driver 200 and the central portion CP2 of the second alignment mark AM2 located on the other side of the display driver 200, may be calculated. In other words, the coordinates (hereinafter, referred to as second coordinates) of the central portion of the imaginary line segment that connects the central portions of the second alignment marks AM2 may be calculated.

Next, as shown in FIG. 37, the display driver 200 and the display panel 100 may be aligned with each other based on the first coordinates and the second coordinates described above, and a bonding process between the display driver 200 and the display panel 100 may be performed in a state where the display driver 200 and the display panel 100 are aligned with each other. For example, the display driver 200 may be located in an aligned state on the display panel 100, and the display driver 200 and the display panel 100 may be physically and electrically connected to each other by a bonding device 900. The anisotropic conductive film described above may be located between the display driver 200 and the display panel 100.

The bonding device 900 may include a head 910 and a support portion 920.

The head 910 of the bonding device 900 may press the display driver 200 from the upper side of the display driver 200. Accordingly, the display driver 200 and the display panel 100 may be physically and electrically connected to each other by the anisotropic conductive film.

The support portion 920 of the bonding device 900 may support the display panel 100 from the lower side of the display panel 100. For example, the support portion 920 may support the bottom surface of the semiconductor substrate SSUB of the display panel 100.

In accordance with one or more embodiments, as shown in FIG. 37, the display panel 100 may further include the encapsulation substrate ENC, and components between the optical layer OPL and the semiconductor substrate SSUB of FIG. 5 described above may be located between the encapsulation substrate ENC and the semiconductor substrate SSUB.

Next, as shown in FIG. 38, a process of checking the alignment state between the display driver 200 and the display panel 100 may be performed. For example, after the imaging device 850 is located under the display panel 100, the imaging device 850 may image the first alignment mark AM1 and the second alignment mark AM2 together in the overlapping area of the display panel 100 and the display driver 200. Here, the imaging device 850 may be, for example, a short wavelength infrared (SWIR) camera.

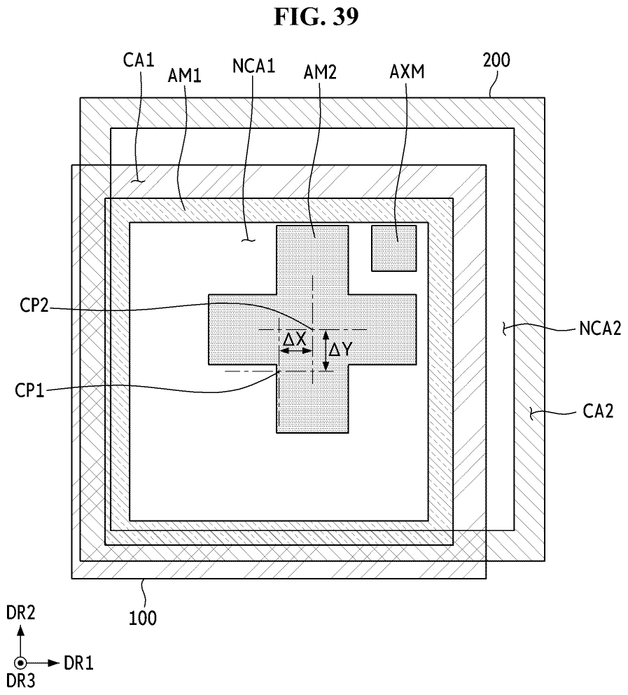

Thereafter, as shown in FIG. 39, when the central portion CP1 of the first alignment mark AM1 and the central portion CP2 of the second alignment mark AM2 do not coincide with each other, the display driver 200 may be moved in at least one of the first direction DR1, the reverse direction of the first direction DR1 (hereinafter, referred to as first reverse direction), the second direction DR2, or the reverse direction of the second direction DR2 (hereinafter, referred to as second reverse direction), so that the display driver 200 and the display panel 100 may be aligned with each other. For example, as shown in FIG. 39, when the central portion (or the coordinates of the central portion of the first alignment mark AM1) of the first alignment mark AM1 and the central portion (or the coordinates of the central portion of the second alignment mark AM2) of the second alignment mark AM2 do not coincide with each other, the display driver 200 may be moved by a device by ΔX in the first reverse direction, and then may be further moved by ΔY in the second reverse direction. Accordingly, the central portion CP1 of the first alignment mark AM1 and the central portion CP2 of the second alignment mark AM2 coincide with each other and, thus, the display driver 200 and the display panel 100 may be aligned with each other.

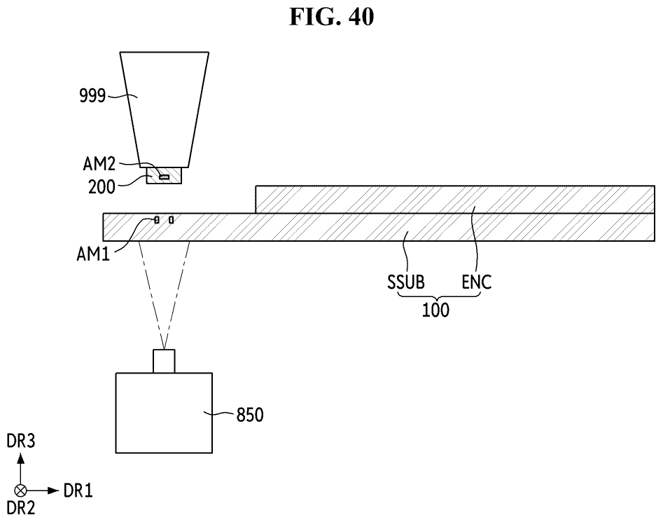

FIG. 40 is a view illustrating a method of manufacturing a display device according to one or more embodiments.

As in the example shown in FIG. 40, the head 999 of the bonding device may adsorb the display driver 200.

The imaging device 850 may image the first alignment mark AM1 of the display panel 100 and the second alignment mark AM2 of the display driver 200 from the lower side of the display panel 100. Whether or not the first alignment mark AM1 and the second alignment mark AM2 coincide with each other is detected in real time by the imaging device 800, and the bonding device 900 (e.g., the head 910 of the bonding device 900) may be moved in at least one of the first direction DR1, the first reverse direction, the second direction DR2, or the second reverse direction according to the detection result. For example, the bonding device 900 is moved such that the central portion of the first alignment mark AM1 and the central portion of the second alignment mark AM2 coincide with each other, so that the display driver 200 and the display panel 100 may be aligned (e.g., preliminary aligned) before the display driver 200 and the display panel 100 are bonded to each other. After the preliminary alignment, the head 910 of the bonding device 900 may be lowered in a direction toward the display panel 100 (e.g., the reverse direction of the third direction DR3 (hereinafter, referred to as third reverse direction)), and then may press the display driver 200, so that the display driver 200 and the display panel 100 may be preliminarily bonded.

In accordance with one or more embodiments, the first alignment mark AM1 of the display panel 100 is made of metal, and the first alignment mark AM1 has a shape surrounding an insulating film made that is a non-metal material, so that the discernment ability (or discrimination ability) of the first alignment mark AM1 may be improved.

In accordance with one or more embodiments, the second alignment mark AM2 of the display driver 200 is made of metal, and the second alignment mark AM2 has a shape surrounded by an insulating film that is a non-metal material, so that the discernment ability of the second alignment mark AM2 may be improved.

In accordance with one or more embodiments, the insulating film surrounded by the first alignment mark AM1 and the second alignment mark AM2 made of a metal material overlap, and the insulating film surrounding the second alignment mark AM2 and the first alignment mark AM1 made of a metal material overlap, so that the discernment ability of the first alignment mark AM1 and the second alignment mark AM2 on the display panel 100 and the display driver 200 bonded to each other may be improved.

Accordingly, even if the display device 10 is manufactured on a wafer including many conductive layers ML1 to ML8, the discernment ability of the first alignment mark AM1 and the second alignment mark AM2 may be improved. Therefore, the first alignment mark AM1 of the display panel 100 and the second alignment mark AM2 of the display driver 200 may be accurately recognized by the imaging device 800.

The display device according to the embodiment can be applied to various electronic devices. The electronic device according to one embodiment includes the display device described above and may further include modules or devices having additional functions in addition to the display device.

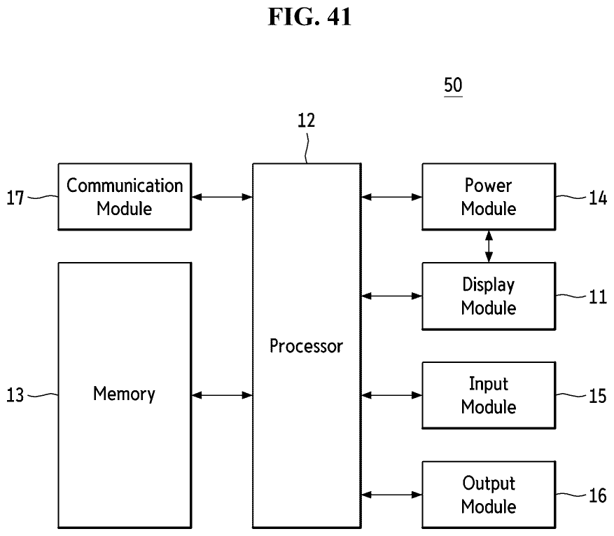

FIG. 41 is a block diagram of an electronic device according to one embodiment. Referring to FIG. 41, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

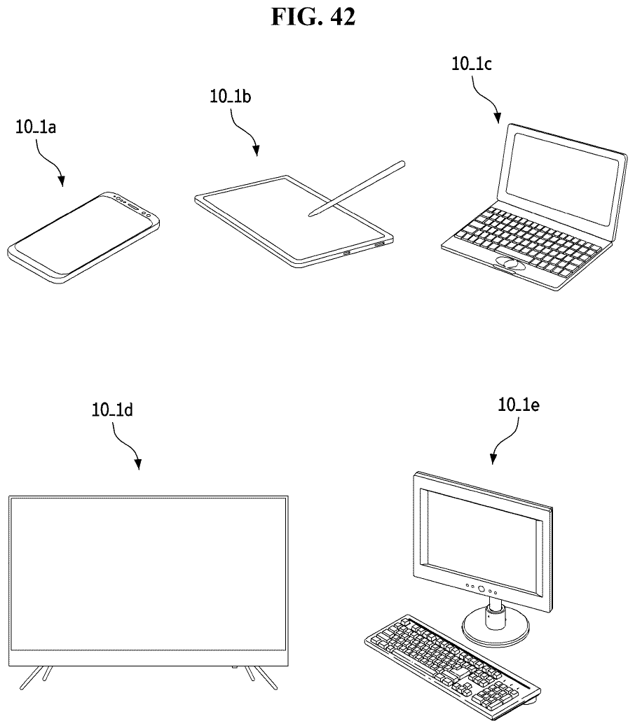

FIGS. 42, 43, and 44 are schematic diagrams of electronic devices according to various embodiments. FIGS. 42 to 44 illustrate examples of various electronic devices to which the display device according to the embodiments is applied.

FIG. 42 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

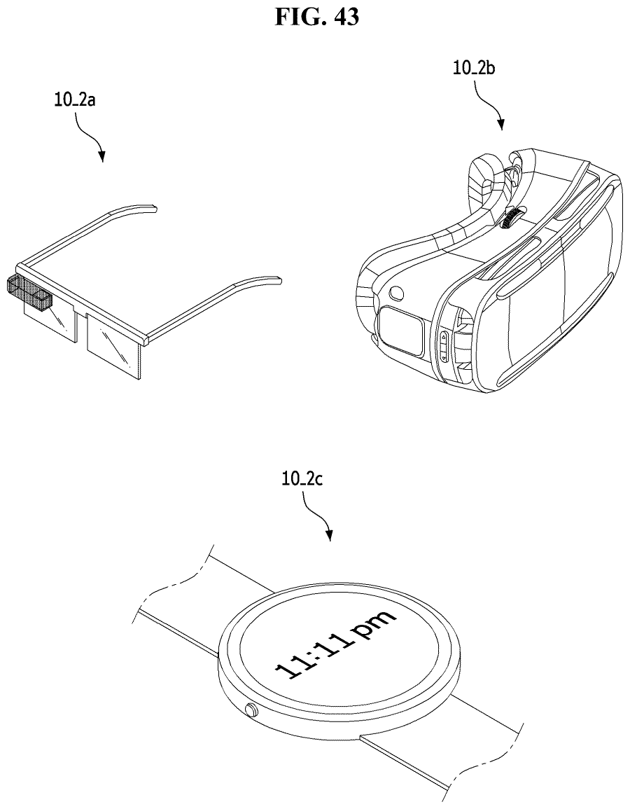

FIG. 43 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

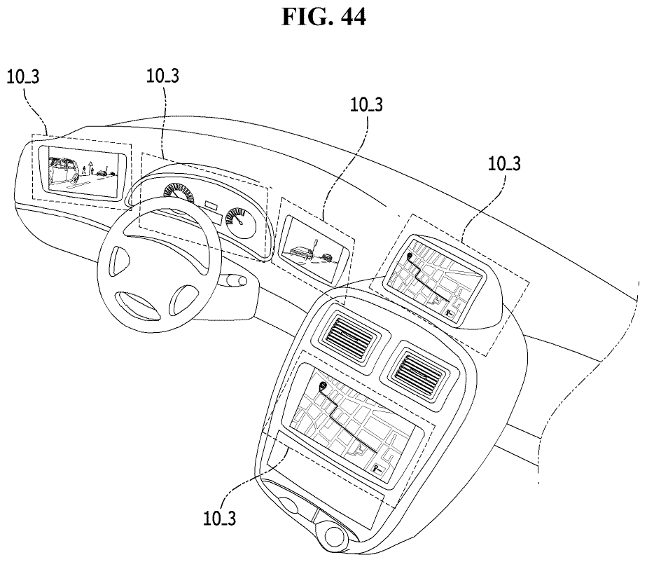

The smart watch 10_2c includes a biometric sensor as an input device, and may provide biometric information recognized by the biometric sensor to the user through the display module. FIG. 44 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other forms without changing the aspects of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel;
a first alignment mark in a first non-circuit area of the display panel, and having a closed curve shape surrounding at least a part of the first non-circuit area;
a display driver connected to the display panel; and
a second alignment mark in a second non-circuit area of the display driver, and surrounded by the second non-circuit area,
wherein the second alignment mark does not overlap the first alignment mark, a metal in the first non-circuit area and a metal in the second non-circuit area.

2. The display device of claim 1, wherein the first alignment mark and the second alignment mark comprise metal,
wherein the first alignment mark is at an edge of the first non-circuit area,
wherein the second alignment mark is at a central portion of the second non-circuit area.

3. The display device of claim 1, wherein the second non-circuit area has an area that is larger than that of the first non-circuit area.

4. The display device of claim 1, wherein an inner region defined by the first alignment mark has an area that is larger than that of the second alignment mark.

5. The display device of claim 1, wherein an inner region defined by the first alignment mark has an area that is smaller than that of the second non-circuit area.

6. The display device of claim 1, wherein the first alignment mark surrounds an insulating film of the first non-circuit area in plan view.

7. The display device of claim 1, wherein the second alignment mark is surrounded by an insulating film of the second non-circuit area in plan view.

8. The display device of claim 1, wherein the first alignment mark surrounds the second alignment mark in plan view.

9. The display device of claim 1, wherein an edge of the second non-circuit area surrounds the first alignment mark in plan view.

10. The display device of claim 1, further comprising a first dummy pattern in the display panel, and at a different layer from the first alignment mark.

11. The display device of claim 10, wherein the first dummy pattern is closer to a substrate of the display panel than the first alignment mark.

12. The display device of claim 10, wherein the first dummy pattern is surrounded by the first alignment mark in plan view.

13. The display device of claim 10, wherein the first dummy pattern is adjacent a corner of the first alignment mark in plan view.

14. The display device of claim 10, wherein the first dummy pattern is in a remaining portion excluding a corner adjacent the first alignment mark.

15. The display device of claim 1, wherein the first alignment mark comprises:
an outer pattern at an edge of the first non-circuit area; and
a protrusion pattern protruding from the outer pattern.

16. The display device of claim 1, further comprising a second dummy pattern in the display driver, and at a different layer from the second alignment mark,
wherein the second dummy pattern is closer to a substrate of the display driver than the second alignment mark.

17. The display device of claim 1, further comprising a third alignment mark in the display panel adjacent to the first alignment mark,
wherein the third alignment mark is adjacent an edge of the display driver.

18. The display device of claim 1, further comprising an auxiliary alignment mark in the second non-circuit area adjacent to one side of the second alignment mark.

19. The display device of claim 1, wherein the first alignment mark has a quadrilateral shape,
wherein the second alignment mark has a cross shape.

20. An electronic device comprising a display device comprising:
a processor;
a battery; and
a display device connected to the processor and the battery,
wherein the display device comprises
a display panel;
a first alignment mark in a first non-circuit area of the display panel, and having a closed curve shape surrounding at least a part of the first non-circuit area;
a display driver connected to the display panel; and
a second alignment mark in a second non-circuit area of the display driver, and surrounded by the second non-circuit area,
wherein the second alignment mark does not overlap the first alignment mark, a metal in the first non-circuit area and a metal in the second non-circuit area.
